(19) United States
(12) Patent Application Publication
(10) Pub. No.: US 2016/0164490 A1
(43) Pub. Date: Jun. 9, 2016

(54) PIEZOELECTRIC DEVICE AND METHOD FOR FABRICATING THE SAME

(71) Applicant: NIHON DEMPA KOGYO CO., LTD., TOKYO (JP)

(72) Inventors: ATSUSHI KAMIJO, SAITAMA (JP); HIROSHI KAWAHARA, SAITAMA (JP)

(73) Assignee: NIHON DEMPA KOGYO CO., LTD., TOKYO (JP)

(21) Appl. No.: 14/225,447

(22) Filed: Mar. 26, 2014

(30) Foreign Application Priority Data
Mar. 27, 2013 (JP) 2013-065318
Mar. 27, 2013 (JP) 2013-065357
Mar. 27, 2013 (JP) 2013-065407

(51) Int. Cl. H03H 9/05; H03H 3/02; H01L 41/18

(52) U.S. Cl. CPC H03H 9/05; H01L 41/18; H03H 3/02

(57) ABSTRACT

The disclosure provides a piezoelectric device includes a piezoelectric vibrating piece and a coating layer. The piezoelectric vibrating piece includes an electrode and an exposed portion. The coating layer is constituted of a material with a sputtering rate lower than a sputtering rate of a material of the electrode, the coating layer covering the exposed portion.

### CROSS-REFERENCE TO RELATED APPLICATIONS

This application claims the priority benefit of Japan applications serial numbers 2013-065318, 2013-065357 and 2013-065407, which are all filed on Mar. 27, 2013. The entirety of each of the above-mentioned patent applications is hereby incorporated by reference herein and made a part of this specification.

### FIELD OF THE INVENTION

This disclosure relates to a piezoelectric device and a method for fabricating the piezoelectric device.

### DESCRIPTION OF THE RELATED ART

A piezoelectric resonator (piezoelectric device) such as a crystal resonator is fabricated by mounting a quartz-crystal vibrating piece (piezoelectric vibrating piece) in a package made of a ceramic or a similar material and by hermetically sealing or vacuum-sealing the package. However, growing market demands for reduction in size, profile, and price of electronic components make it difficult to use a ceramic package. In order to meet these demands, a piezoelectric resonator using a glass package has been proposed (for example, see Japanese Unexamined Patent Application Publication No. 2004-6525 and Japanese Unexamined Patent Application Publication No. 2012-74649).

Exemplary structures of a glass package include: a structure where a quartz-crystal vibrating piece is mounted on a depressed portion formed on one of a lid and a base bonded to each other; and a structure where a lid and a base are respectively bonded to a front surface and a back surface of a quartz-crystal vibrating piece with a framing portion (for example, see Japanese Unexamined Patent Application Publication No. 2000-68780). Since both structures can be fabricated in wafer level, reduction in size, profile, and price can be achieved, differing from a conventional ceramic package.

In the fabrication of the glass packages having the above-described structures, examples of proposed bonding methods for bonding a glass wafer to a glass wafer, or a glass wafer to a crystal wafer, include: a direct wafer bonding method; an anodic bonding method; a metal pressure welding method; a low melting point glass bonding method; a plasma activation bonding method; an ion-beam activation bonding method; and similar bonding methods. The direct wafer bonding method disadvantageously requires high temperature heat treatment for obtaining sufficient bonding strength, which is problematic for a bonding method for a crystal resonator. The anodic bonding method is a bonding method for bonding a glass wafer containing alkali ions, and generates a gas during bonding, which disadvantageously increases pressure in the package.

The metal pressure welding method is a bonding method for bonding via a metal such as an AuSn eutectic metal, and thus the metal pressure welding method requires film formation of an adhesive layer or a barrier layer, and patterning, which disadvantageously increases fabrication cost. The low melting point glass bonding method generates a gas from a low melting point glass paste during bonding, which disadvantageously increases pressure in the package. The plasma activation bonding method is considered to be difficult to bond in a vacuum atmosphere. The ion-beam activation bonding method involves irradiating an argon beam or similar beam to the wafers to remove contamination on the surfaces of the wafers and bringing both surfaces into contact with each other, and thus would allow bonding a variety of materials at room temperatures.

The ion-beam activation bonding method has an activation process by irradiating an ion beam, and a bonding process for bonding the wafers, which are generally performed in the same chamber. Accordingly, stopping argon supply immediately after the activation process and evacuating the chamber allows bonding the wafers with keeping a low pressure required for a crystal resonator. Note that since a member of an ion source main body and an inner wall of a chamber are simultaneously sputtered during the irradiation of ion beam, an iron (Fe), a chrome (Cr), and an aluminum (Al), which are constituent materials (stainless steel or aluminum alloy) of those members, are deposited on the surfaces of wafers (for example, Japanese Unexamined Patent Application Publication No. 2007-324195. Thus, in the ion-beam activation bonding method, since the etching caused by the sputtering action on the surface of the wafers and an adherence (deposit) of an iron, a chrome, and an aluminum are simultaneously occurred with the irradiation of an ion beam, a strong bonding between glass or crystal wafers is achieved.

Incidentally, in the glass package of the type having the lid and the base, various kinds of wiring such as a through electrode and a connecting electrode are formed on, for example, the surfaces of the base. An excitation electrode and an extraction electrode are also formed on the quartz-crystal vibrating piece mounted on the base, and this extraction electrode is electrically connected to the connecting electrode of the base. Also, in the type where the front surface and the back surface of the quartz-crystal vibrating piece having the framing portion are respectively bonded to the lid and the base of the glass package, a various kind of electrodes are formed on the base. An excitation electrode and an extraction electrode are also formed on the quartz-crystal vibrating piece.

In both types, when the ion-beam activation bonding method is used for bonding the lid, the electrodes formed on the quartz-crystal vibrating piece and the base are exposed to the irradiation of ion beam. This causes etching by sputtering action of argon and deposition of a metal element that constitute the inner wall of the chamber. The etching amounts of the electrodes of the quartz-crystal vibrating pieces and the deposit amounts of the metal element vary depending on the mounting position of the quartz-crystal vibrating piece or the forming positions of the quartz-crystal vibrating pieces within the wafer. This distribution is equivalent to a distribution of the resonance frequency variation of the quartz-crystal vibrating pieces within the wafer surface. The frequency variation shifts toward the positive side in the region where the etching amounts of the electrodes are larger than the deposit amounts of the metal elements. In contrast the frequency variation shifts toward the negative side in the region where the etching amounts of the electrodes are smaller than the deposit amounts of the metal elements. In the fabrication of a crystal resonator, such a frequency variation caused after bonding of the wafers unfortunately decreases the product yield.

A need thus exists for a piezoelectric device and a method for fabricating the piezoelectric device without being susceptible to the drawbacks mentioned above.

### SUMMARY OF THE INVENTION

This disclosure provides a piezoelectric device that includes a piezoelectric vibrating piece and a coating layer. The piezoelectric vibrating piece includes an electrode and an exposed portion. The coating layer is constituted of a material with a sputtering rate lower than a sputtering rate of a material of the electrode, the coating layer covering the exposed portion.

### BRIEF DESCRIPTION OF THE DRAWINGS

The foregoing and additional features and characteristics of this disclosure will become more apparent from the following detailed description considered with reference to the accompanying drawings, wherein:

FIG. 1A is a developed perspective view illustrating a piezoelectric device according to a first embodiment;

FIG. 1B is a cross-sectional view of the piezoelectric device according to the first embodiment taken along the line IB-IB of FIG. 1A;

FIG. 2A is a plan view illustrating a piezoelectric vibrating piece according to the first embodiment;

FIG. 2B is a cross-sectional view of the piezoelectric vibrating piece according to the first embodiment taken along the line IIB-IIB of FIG. 2A;

FIG. 3A is a perspective view illustrating a piezoelectric wafer according to the first embodiment in a fabrication process;

FIG. 3B is a perspective view illustrating a lid wafer and a base wafer according to the first embodiment in the fabrication process;

FIG. 4 is a schematic view illustrating an ion beam activation bonding device;

FIG. 5 is a cross-sectional view illustrating a piezoelectric device according to a second embodiment;

FIG. 6A is a developed perspective view illustrating a piezoelectric device according to a third embodiment;

FIG. 6B is a cross-sectional view of the piezoelectric device according to the third embodiment taken along the line VIB-VIB of FIG. 6A;

FIG. 7A is a plan view illustrating a piezoelectric vibrating piece according to the third embodiment;

FIG. 7B is a cross-sectional view of the piezoelectric vibrating piece according to the third embodiment taken along the line VIIB-VIIB of FIG. 7A;

FIG. 8 illustrates a fabrication process of the piezoelectric device according to the third embodiment

FIG. 9 is a diagram illustrating a relation between positions of crystal resonators within a piezoelectric wafer and the frequency variation;

FIG. 10A is a developed perspective view illustrating a piezoelectric device according to a fourth embodiment;

FIG. 10B is a cross-sectional view of the piezoelectric device according to the fourth embodiment taken along the line XB-XB of FIG. 10A;

FIG. 11A is a plan view illustrating a piezoelectric vibrating piece according to the fourth embodiment;

FIG. 11B is a cross-sectional view of the piezoelectric vibrating piece according to the fourth embodiment taken along the line XIB-XIB of FIG. 11A;

FIG. 12 is a cross-sectional view illustrating a piezoelectric device according to a fifth embodiment;

FIG. 13A is a developed perspective view illustrating a piezoelectric device according to a sixth embodiment;

FIG. 13B is a cross-sectional view of the piezoelectric device according to the sixth embodiment taken along the line XIIIB-XIIIB of FIG. 13A;

FIG. 14A is a plan view illustrating a piezoelectric vibrating piece according to the sixth embodiment;

FIG. 14B is a cross-sectional view of the piezoelectric vibrating piece according to the sixth embodiment taken along the line XIVB-XIVB of FIG. 14A;

FIG. 15 is a diagram illustrating a relation between positions of crystal resonators within a piezoelectric wafer and the frequency variation;

FIG. 16A is a developed perspective view illustrating a piezoelectric device according to a seventh embodiment;

FIG. 16B is a cross-sectional view of the piezoelectric device according to the seventh embodiment taken along the line XVIB-XVIB of FIG. 16A;

FIG. 17A is a plan view illustrating a piezoelectric vibrating piece according to the seventh embodiment;

FIG. 17B is a cross-sectional view of the piezoelectric vibrating piece according to the seventh embodiment taken along the line XVIIB-XVIIB of FIG. 17A;

FIG. 18 is a cross-sectional view illustrating a piezoelectric device according to an eighth embodiment;

FIG. 19A is a developed perspective view illustrating a piezoelectric device according to a ninth embodiment;

FIG. 19B is a cross-sectional view of the piezoelectric device according to the ninth embodiment taken along the line XIXB-XIXB of FIG. 19A;

FIG. 20A is a plan view illustrating a piezoelectric vibrating piece according to the ninth embodiment;

FIG. 20B is a cross-sectional view of the piezoelectric vibrating piece according to the ninth embodiment taken along the line XXB-XXB of FIG. 20A; and

FIG. 21 is a diagram illustrating a relation between positions of crystal resonators within a piezoelectric wafer and the frequency variation.

### DESCRIPTION OF THE EMBODIMENTS

The following describes the embodiments of this disclosure with reference to the drawings. This disclosure, however, in not limited to these. In addition, in the following embodiments, the drawings are appropriately scaled, for example, partially enlarged or highlighted to describe the embodiments. In each drawing below, the directions are indicated using the XYZ coordinate system. In this XYZ coordinate system, the XZ plane corresponds to a plane parallel to a front surface of a piezoelectric vibrating piece. In the XZ plane, the X direction corresponds to a longitudinal direction of the piezoelectric vibrating piece, and the Z direction corresponds to a direction perpendicular to the X direction. The Y direction corresponds to a direction perpendicular to the XZ plane (the thickness direction of the piezoelectric vibrating piece). The explanations are given assuming that a direction indicated by the arrow is the positive direction, and a direction opposite to the positive direction is the negative direction in each of the X direction, the Y direction, and the Z direction.

### Configuration of Piezoelectric Device 100 According to the First Embodiment

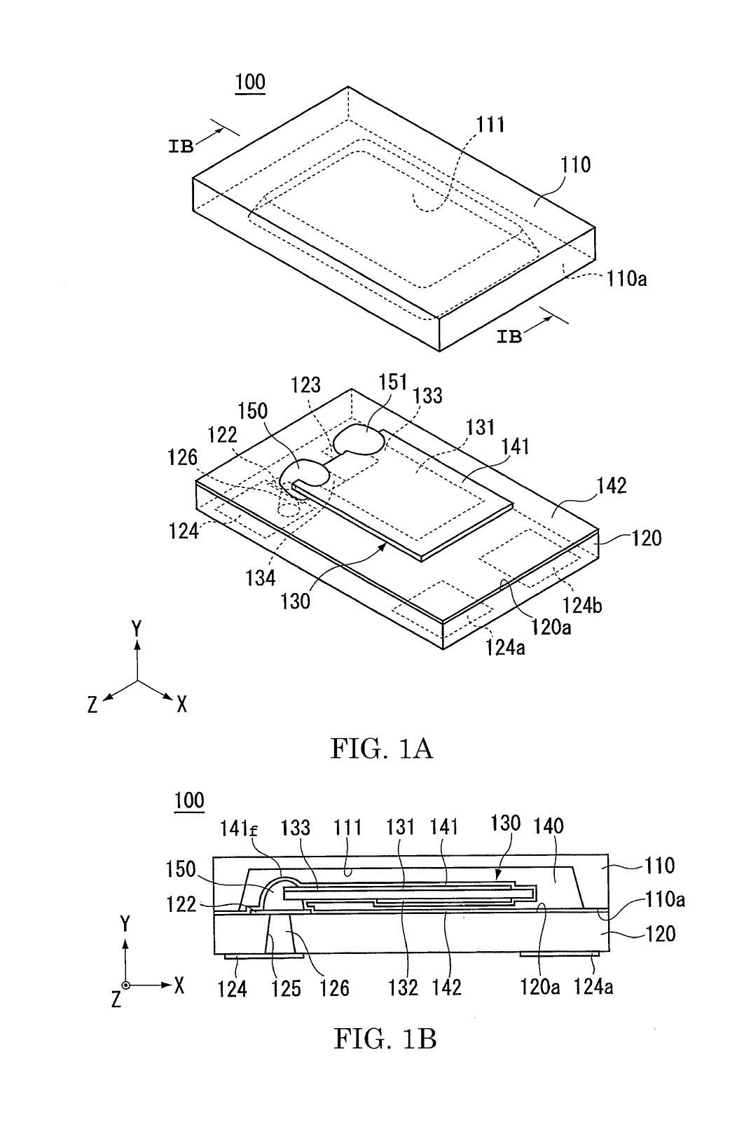

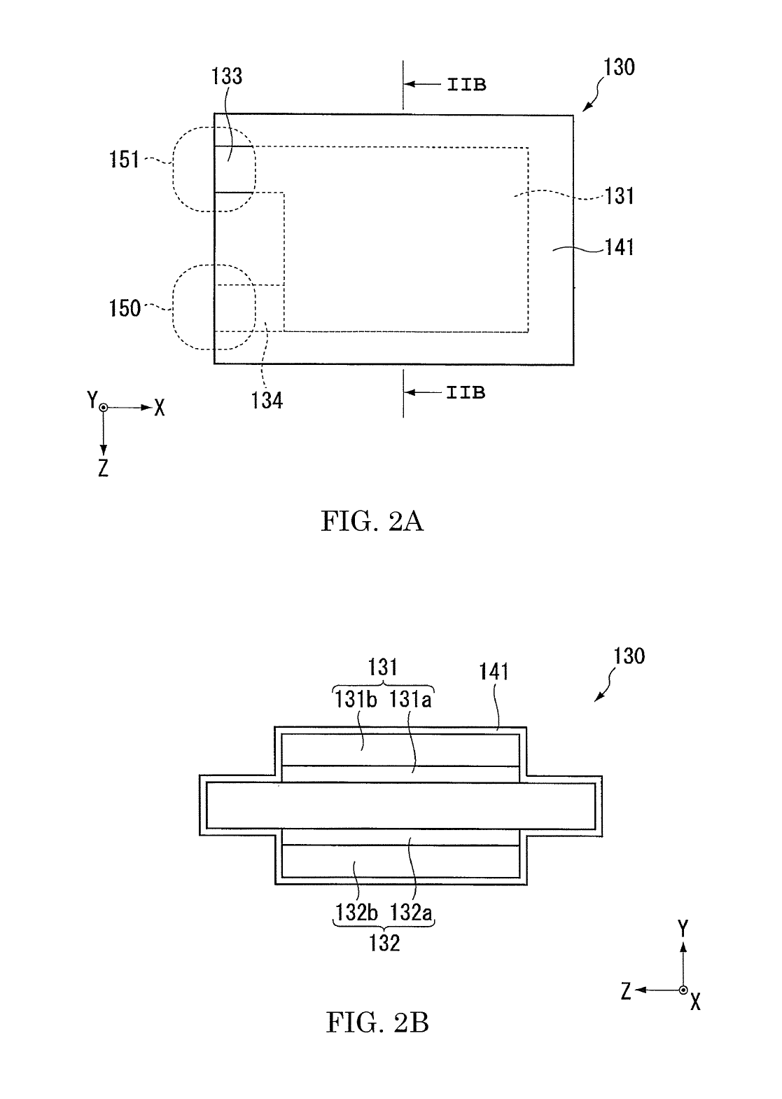

The following describes a piezoelectric device 100 according to the first embodiment with reference to FIG. 1A, FIG. 1B, FIG. 2A, and FIG. 2B. As illustrated in FIG. 1A, the piezoelectric device 100 is a piezoelectric resonator including a lid 110, a base 120, and a piezoelectric vibrating piece 130. The lid 110 and the base 120 are made of a borosilicate glass. This, however, should not be constrained in a limiting sense. Examples of the materials of the lid 110 and the base 120 also include: glasses such as a soda-lime glass, a non-alkali glass and a quartz; aluminum compounds such as a silicon-aluminum compound and a ceramic-aluminum compound; or a material that mainly include the above-described materials and added other various materials. In addition, the lid 110 and the base 120 can be made of different kinds of materials instead of being made of the same kind of material. Use of the same kind of material, however, results in a uniform thermal expansion coefficient, which prevents stresses from being generated by temperature change.

The lid 110 is made of a plate-shaped member having a rectangular shape in plan view, and has a depressed portion 111 at the central portion of the back surface (−Y-side surface) as illustrated in FIG. 1A. The depressed portion 111 is surrounded by a bonding surface 110a to be bonded to the base 120 described below. The bonding surface 110a has a sufficient flatness appropriate for bonding by the ion-beam activation bonding method (typically, average roughness Ra is around 1 nm).

Similar to the lid 110, the base 120 is a plate-shaped member having a rectangular shape in plan view. As illustrated in FIG. 1B, bonding the bonding surface 110a of the lid 110 to a front surface 120a (+Y-side surface) of the base 120 forms a cavity 140 (housing space), which houses the piezoelectric vibrating piece 130 described below. Note that similar to the bonding surface 110a, the bonding portion of the front surface 120a, which is to be bonded to the bonding surface 110a of the lid 110, has a sufficient flatness appropriate for bonding by the ion-beam activation bonding method (typically, average roughness Ra is around 1 nm).

At the −X side of the front surface 120a of the base 120, connecting electrodes 122 and 123 having a rectangular shape are aligned in the Z direction. The four corners of the back surface (−Y-side surface) of the base 120 respectively include external electrodes 124 and dummy electrodes 124a and 124b each having a rectangular shape. Note that the external electrode at the −X side and −Z-side is not illustrated in FIG. 1A since it is hidden behind the piezoelectric vibrating piece 130. The external electrodes 124 are used as a pair of mounting terminals when the piezoelectric device 100 is implemented on a substrate. Note that the dummy electrodes 124a and 124b are not electrically connected to other electrodes.

At the positions corresponding to the connecting electrodes 122 and 123, through holes 125 are formed that respectively penetrate the base 120 in the Y direction. These through holes 125 each has a through electrode 126. The through electrode 126 connects the connecting electrode 122 and the external electrode 124. Note that the connecting electrode 123 is also electrically connected to the external electrode via the not illustrated through electrodes 126.

The connecting electrodes 122 and 123 and external electrodes 124 include a conductive metal film. These metal films have a layered structure where, for example, a chrome (Cr), a titanium (Ti), a nickel (Ni), a nickel-chrome (NiCr) alloy, a nickel-titanium (NiTi) alloy, or a nickel-tungsten (NiW) alloy is formed as a base layer on which a gold (Au) or a silver (Ag) is formed as a layer. The through electrodes 126 are formed by filling the through holes 125 of the base 120 by, for example, copper plating.

As illustrated in FIG. 2A, the piezoelectric vibrating piece 130 is made of a rectangular plate-shaped member having a longitudinal side in the X direction and a short side in the Z direction. For example, an AT-cut quartz-crystal vibrating piece is used as the piezoelectric vibrating piece 130. An AT-cut method can advantageously obtain excellent frequency characteristics when a piezoelectric device such as a crystal resonator or a crystal oscillator is used at near ordinary temperature. The AT-cut method is a cutting method for cutting out a quartz crystal at an angle inclined by 35° 15′ around the crystallographic axis with respect to the optical axis of the three crystallographic axes of a synthetic quartz crystal, and the three crystallographic axes are the electrical axis, the mechanical axis, and the optical axis.

On the front surface (+Y-side surface) of the piezoelectric vibrating piece 130, a rectangular shaped excitation electrode 131 is formed; while on the back surface (−Y-side surface), a rectangular shaped excitation electrode 132 is similarly formed. The excitation electrodes 131 and 132 are opposed each other sandwiching the piezoelectric vibrating piece 130 in the Y direction, and have the approximately same size. The piezoelectric vibrating piece 130 vibrates at a predetermined vibration frequency by applying a predetermined AC voltage to the excitation electrodes 131 and 132. Note that a mesa shape, where the middle layer portion is thicker than the peripheral portion, can be formed on at least one of the front surface and back surface of the piezoelectric vibrating piece 130. When the mesa shape is formed, the excitation electrodes 131 and 132 are formed corresponding to the mesa shape.

The front surface and back surface of the piezoelectric vibrating piece 130 respectively include extraction electrodes 133 and 134 that are respectively and electrically connected to the excitation electrodes 131 and 132. The extraction electrode 133 is formed by being extracted from the excitation electrode 131 in −X direction on the front surface of the piezoelectric vibrating piece 130. The extraction electrode 134 is formed by being extracted from the excitation electrode 132 in the −X direction on the back surface of the piezoelectric vibrating piece 130. Note that the extraction electrode 133 and the extraction electrode 134 are not electrically connected to each other. Also, the extraction electrode 133 may be extracted from the end portion of the −X side of the piezoelectric vibrating piece 130 to the back surface of the piezoelectric vibrating piece 130.

The excitation electrodes 131 and 132, and the extraction electrodes 133 and 134 are formed of a conductive metal film. As illustrated in FIG. 2B, this metal film has a two-layered structure which includes base layers 131a and 132a for increasing adhesion with a quartz-crystal material, and main electrode layers 131b and 132b. The base layers 131a and 132a include, for example, a chrome (Cr), a titanium (Ti), a nickel (Ni), a nickel-chrome (NiCr) alloy, a nickel-titanium (NiTi) alloy, or a nickel-tungsten (NiW) alloy. The main electrode layers 131b and 132b are formed of, for example, a gold (Au) or a silver (Ag).

Also, as illustrated in FIG. 2B, the exposed portion of the piezoelectric vibrating piece 130 including the excitation electrodes 131 and 132 and the extraction electrodes 133 and 134 is coated by a coating layer 141. However, the portions of the extraction electrodes 133 and 134, which are connected to conductive adhesives 150 and 151 described later, are not coated by the coating layer. In addition, as illustrated in FIG. 1B, the surfaces of the conductive adhesives 150 and 151 are coated by a coating layer 141f, while the front surface 120a of the base 120 is coated by a coating layer 142. It is, however, optional that whether or not the surface of the conductive adhesives 150 and 151, and the front surface 120a of the base 120 are coated by the coating layers 141f and 142. Note that although the film thickness of the coating layers 141, 141f, and 142 is set to 2 nm, the film thickness is set to several nm to several 10 nm with no specific restriction. In addition, the side surfaces and the back surface of the base 120 may be coated by the coating layer 142.

The coating layers 141, 141f, and 142 may include an oxide based insulator or an oxide based dielectric of any of an aluminum oxide (Al₂O₃), a silicon oxide (SiO₂), a magnesium oxide (MgO), a titanium oxide (TiO₂), and a zirconium oxide (ZrO₂), and the sputtering rate of the oxide based insulator or the oxide based dielectric is lower than the sputtering rate of the metal used as the main electrode layers 131b and 132b of the excitation electrodes 131 and 132. Also, the coating layers 141, 141f, and 142 may include a nitride based insulator or a nitride based dielectric of any of a boron nitride (BN), an aluminum nitride (AlN), and a silicon nitride (SiN), and the sputtering rate of the nitride based insulator or the nitride based dielectric is lower than that of the metals used for the main electrode layers 131b and 132b of the excitation electrodes 131 and 132.

The following is the sputter etching effects by the irradiation of argon ion beam (argon beam). When an ion beam is vertically irradiated, assuming that the sputtering rate of silver is normalized to 1, a sputtering rate of gold is 0.71, then, for example, a sputtering rate of aluminum oxide is 0.07, and a sputtering rate of silicon oxide is 0.22, which are considerably low.

Note that the amount of frequency variation due to the sputtering of the excitation electrodes 131 and 132 is proportional to the etched mass of the excitation electrodes 131 and 132 by sputtering. Accordingly, use of, for example, an oxide based insulator such as an aluminum oxide, a silicon oxide, a magnesium oxide, and a titanium oxide whose density is low, or a nitride based insulator such as a boron nitride, an aluminum nitride, and a silicon nitride, the multiplication of the sputtering rate and the density of the oxide based insulator or the nitride based insulator is a low number so that the oxide based insulator or the nitride based insulator is used as the coating layer 141 or similar coating layer would advantageously allow the amount of frequency variation to decrease.

As illustrated in FIG. 1A and FIG. 1B, the piezoelectric vibrating piece 130 is supported on the front surface 120a of the base 120 by the conductive adhesives 150 and 151. The extraction electrode 134 and connecting electrode 122 are electrically connected via the conductive adhesive 150, while the extraction electrode 133 and the connecting electrode 123 are electrically connected via the conductive adhesive 151. Then, the lid 110 and the base 120 are bonded to each other. Accordingly, the piezoelectric vibrating piece 130 is housed in the cavity 140. The inside of the cavity 140 is sealed under a vacuum atmosphere or an inert gas atmosphere of, for example, a nitrogen gas. Note that the bonding surface 110a of the lid 110 and the front surface 120a of the base 120 are directly bonded to each other without, for example, a bonding material.

Thus, according to the piezoelectric device 100, since the coating layer 141 is formed to coat the exposed portion of the piezoelectric vibrating piece 130, the excitation electrodes 131 and 132 are coated by the coating layer 141 that has a low sputtering rate by which the damage and similar failures of the excitation electrodes 131 and 132 can be prevented, and thus the reliability of the piezoelectric device 100 can be improved. In addition, since the coating layers 141f and 142 are also formed on the front surface 120a of the base 120, formed on the conductive adhesive 150, and formed on similar areas, the damage and similar failures of the connecting electrode 122, of the conductive adhesive 150, and of similar areas can be prevented, and thus the reliability of the piezoelectric device 100 can be improved.

### Fabricating Method of Piezoelectric Device 100

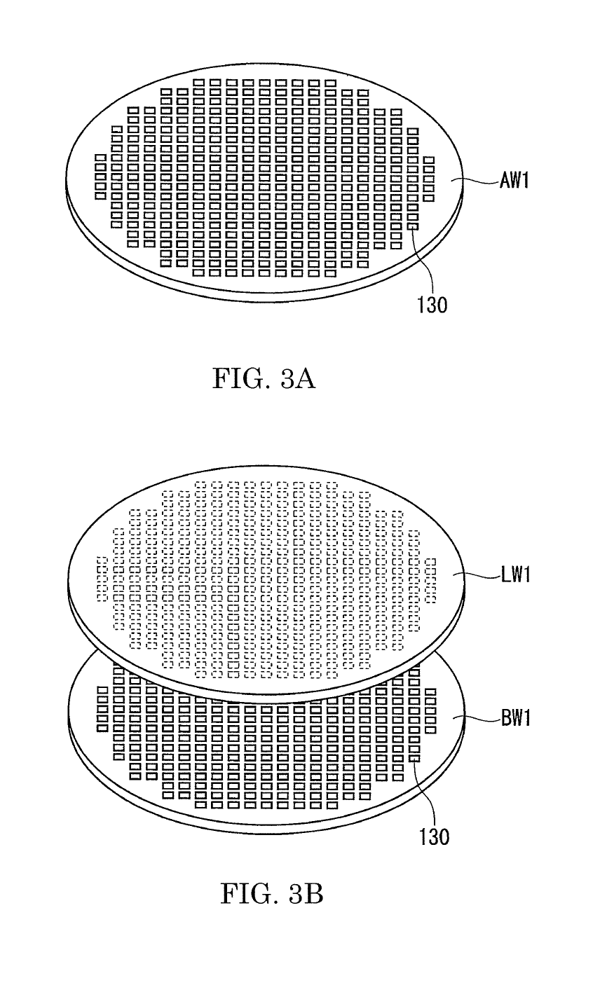

The following describes a method for fabricating the piezoelectric device 100 with reference to FIGS. 3A and 3B. The piezoelectric device 100 is fabricated using a method referred to as wafer level packaging. In the fabrication of the piezoelectric vibrating piece 130, a multiple patterning is performed on a piezoelectric wafer AW1 from which individual pieces are cut out. First, as illustrated in FIG. 3A, the piezoelectric wafer AW1 is prepared. The piezoelectric wafer AW1 is cut out from a crystalline body by the AT-cut method.

Then, the piezoelectric wafer AW1 is formed by, for example, etching or cutting such that the thickness (width of the Y-axis direction) of the wafer is decreased and is adjusted to obtain the desired frequency characteristic. Note that a mesa shape, where the central portion is thicker than the peripheral portion, can be formed by, for example, the photolithography and etching. Next, the excitation electrodes 131 and 132 are respectively formed on the front surface and the back surface of the piezoelectric wafer AW1 (Piezoelectric Vibrating Piece 130).

The excitation electrodes 131 and 132 are formed as follows: the base layers 131a and 132a of a nickel-chrome alloy or similar material are formed by, for example, sputtering or vacuum evaporation using a metal mask stencil; and the main electrode layers 131b and 132b of a gold or similar material are aimed on the base layers 131a and 132a. Note that the excitation electrodes 131 and 132 may be patterned by, for example, the photolithography and etching instead of using the metal mask stencil. The extraction electrodes 133 and 134 may be formed separately, which are typically faulted at the same time when the excitation electrodes 131 and 132 are formed. After the excitation electrodes 131 and 132 are formed, the piezoelectric wafer AW1 is diced along the scribe line. Accordingly, the individual piezoelectric vibrating pieces 130 are completed.

Similar to the piezoelectric vibrating piece 130, in the fabrication of the lid 110 and the base 120, the multiple patterning is performed on a lid wafer LW1 and a base wafer BW1 from which individual pieces are cut out. For example, a borosilicate glass is used as the lid wafer LW1 and as the base wafer BW1. On the lid wafer LW1, the depressed portion 111 for forming the cavity 140 is formed by sand-blasting or wet etching. Meanwhile, on the base wafer BW1, the through hole 125 and similar hole are formed by sand-blasting or wet etching.

On the base wafer BW1, the through electrode 126 and similar electrode are formed by filling the through hole 125 and similar hole by, for example, copper plating. The connecting electrodes 122 and 123 are formed on the front surface of the base wafer BW1, while the external electrodes 124 are formed on the back surface of the base wafer BW1 such that the connecting electrodes 122 and 123, and the external electrodes 124 are electrically connected to the through electrodes 126. The dummy electrodes 124a and 124b are also formed at the same time. The connecting electrodes 122 and 123, and external electrodes 124 are formed by depositing a gold or a silver on the base layer of, for example, a nickel-tungsten or similar by sputtering or vacuum evaporation using, for example, a metal mask stencil.

Next, on the base wafer BW1, the individual piezoelectric vibrating pieces 130 are mounted by the conductive adhesives 150 and 151 (mounting process). The excitation electrodes 131 and 132 of the piezoelectric vibrating piece 130 are electrically connected to the external electrodes 124 by the conductive adhesives 150 and 151.

Next, the coating layers 141, 141f, and 142 of an insulator or a dielectric are formed on the exposed portion of the piezoelectric vibrating piece 130, the exposed portion of the base 120, the conductive adhesive 150, and similar part (coating process). For example, an atomic layer deposition (ALD) method is used for the coating process. The ALD method is a film deposition method that forms mono-layers one by one by repeating, for each molecular layer, a cycle including: the adsorption of the molecules of a raw material compound (precursor) to the surface of a substrate placed in a vacuum chamber; the formation of the molecular film by reaction; and the removal of the excess molecules by purging. Accordingly, use of the ALD method that has a self-stop mechanism of surface chemical reaction allows controlling the film thickness with an accuracy of 0.1 nm. Furthermore, an excellent step coverage performance of the ALD method allows forming films having high aspect ratio on the inner wall of holes and a narrow void portion. Accordingly, forming a film on the piezoelectric vibrating piece 130 using the ALD method allows precisely predicting a frequency deviation amount due to the film formation in advance. Note that the ALD method allows forming films of a wide variety of insulator materials or dielectric materials. In addition, the film thickness of the coating layers 141, 141f, and 142 formed by the ALD method is not specially restricted but is set to about 1 nm to several 10 nm to provide the thickness to the extent that the coating layers do not dissipate by the ion radiation, while so as not to make the frequency variation caused by forming the insulator layers or dielectric layers too large.

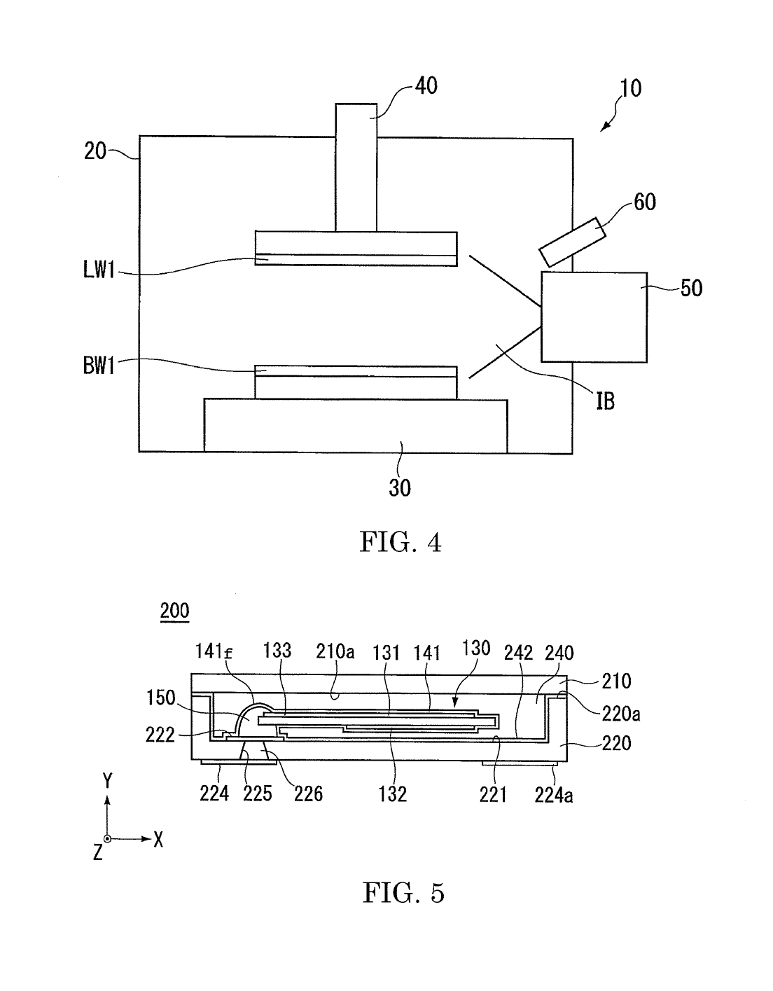

Next, the lid wafer LW1 is bonded to the base wafer BW1 by the ion-beam activation bonding method (lid bonding process). As illustrated in FIG. 4, the ion-beam activation bonding method is performed using an ion beam activation bonding apparatus 10. As illustrated in FIG. 4, the ion beam activation bonding apparatus 10 includes a vacuum chamber 20, an alignment stage 30 having a wafer holder, a pressure applying mechanism 40 having a wafer holder, an ion source 50 disposed for irradiating an ion beam to a bonding surface, and a neutralized electron source 60. The vacuum chamber 20 is evacuated by an evacuation pump (not illustrated) (for example, turbomolecular pump), and a vacuum atmosphere is formed in the vacuum chamber 20. An argon gas is supplied to the ion source 50 and the neutralized electron source 60 via respective mass flow meters.

The lid wafer LW1 is held on the wafer holder of the pressure applying mechanism 40 by, for example, an electrostatic chuck, while the base wafer BW1 is held on the wafer holder of the alignment stage 30. This makes the lid wafer LW1 and the base wafer BW1 placed with their respective bonding surfaces being opposed each other. Next, after the vacuum chamber 20 is evacuated to a predetermined pressure, an argon beam (ion beam) IB is irradiated to both wafers from the ion source 50. Note that the argon beam IB is neutralized by the neutralized electron source 60.

The surfaces of the lid wafer LW1 and base wafer BW1 are sputter-etched to be decontaminated by the argon beam IB. At this time, having been exposed to the argon plasma, the members of the ion source 50, such as an anode, are sputtered. Accordingly, the argon beam IB irradiated from the ion source 50 includes an iron and a chrome, which are components of a stainless steel of which the ion source 50 is made. In addition, since the argon beam IB irradiated from the ion source 50 has a large divergence angle, the argon beam IB sputters not only the lid wafer LW1 and a similar wafer but also the stainless steel of the inner wall in the vacuum chamber 20 and other components that are made of aluminum alloy. The argon beam IB sputtering would make an iron, a chrome, an aluminum and similar elements deposited on the lid wafer LW1 and similar wafer. Namely, etching and deposition are carried out simultaneously on the surfaces of the lid wafer LW1 and the base wafer BW1. Accordingly, the coating layers 141, 141f, and 142 become in a state where an iron, a chrome, an aluminum, or similar element are mixed to an insulator film or a dielectric film, or in a state of a layered film of an insulator film or similar film and an iron, a chrome, an aluminum, and similar elements.

As described above, the coating layer 141 formed on the exposed portion of the piezoelectric vibrating piece 130 has a sputtering rate lower than that of a gold and a silver used as the excitation electrode 131 and 132. Accordingly, the excitation electrodes 131 and 132 are not etched carelessly by the irradiation of the argon beam IB since they are coated by the coating layer 141. Similar to the excitation electrodes 131 and 132, the connecting electrode 122 and similar, and the conductive adhesive 150 and similar of the base 120 are not etched carelessly by the irradiation of the argon beam IB since they are coated by the coating layers 141f and 142.

Next, after the argon beam IB is irradiated for the predetermined time period, the lid wafer LW1 and the base wafer BW1 are aligned to each other, then both wafers are bonded to each other with the condition of the predetermined pressure and press-contact time by the pressure applying mechanism 40. Afterwards, the bonded wafer is removed from the ion beam activation bonding apparatus 10, and is diced along the scribe line to complete individual piezoelectric devices 100. Note that the external electrode 124 and similar electrode can be formed on the back surface of the base wafer BW1 after the lid wafer LW1 and the base wafer BW1 are bonded to each other.

Incidentally, since a gold and a silver, which are the materials of the main electrodes, are metals having a high density and a high sputtering rate, when the ion beam is irradiated to sputter them during bonding by the ion-beam activation bonding method, the frequency of the piezoelectric vibrating piece 130 significantly shifts toward the positive side (the resonance frequency increases). Furthermore, the etched amount is sensitive to the strength of the beam irradiated within the wafer surface, the frequency shift amounts are largely distributed within the wafer surface. On the other hand, since the members of the ion source 50 and the inner wall of the vacuum chamber 20 are sputtered, an iron, a chrome, and an aluminum, which are their constituent materials, are deposited on the excitation electrode 131 and similar. However, these metals have a low density compared with a gold or a silver, and the film thickness is several nanometer, accordingly the frequency of the piezoelectric vibrating piece 130 slightly shifts toward the negative side (the resonance frequency decreases).

On the other hand, the coating layers 141, 141f, and 142 have a low sputtering rate, and also the argon beam IB is irradiated to the coating layers 141, 141f, and 142 from the direction inclined by approximately 90 degree with respect to the vertical direction of the lid wafer LW and similar as illustrated in FIG. 4, accordingly, the actual sputtering rate is significantly low. Consequently, the coating layer 141 and similar layers are hardly etched, and only metal elements such as an iron, a chrome, and an aluminum are deposited on the coating layer 141 and similar layers.

Since the deposit amounts of the metals can be constant without being distributed within the wafer surfaces by decreasing the film thickness to several nm and optimizing the irradiation condition, the resonance frequencies of the piezoelectric devices 100 after bonding of the wafers uniformly shift toward the negative side within the wafer surface. In the frequency adjustment process to be done before the bonding process, adjusting the resonance frequencies with considering this shifting amount allows producing, with high production yield, the piezoelectric devices 100 having the desired resonance frequency after the bonding of the wafers by wafer level packaging using glass.

Thus, the fabrication method of the piezoelectric device 100 allows preventing the excitation electrode 131 and similar electrode of the piezoelectric vibrating piece 130 from being etched carelessly, and reducing the variation of the resonance frequency of the piezoelectric vibrating piece 130 to prevent the production of inferior products.

### Configuration of Piezoelectric Device 200 According to Second Embodiment

The following describes the second embodiment. In the following description, like reference numerals designate identical or corresponding parts of the first embodiment, and therefore such elements will not be further elaborated here. FIG. 5 illustrates a piezoelectric device 200 according to the second embodiment. In addition, FIG. 5 illustrates a cross-sectional view taken along the line corresponding to the line IB-IB of FIG. 1A. Similar to the first embodiment, the piezoelectric device 200 uses a piezoelectric vibrating piece 130.

The piezoelectric device 200 includes a lid 210 and a base 220. As illustrated in FIG. 5, the lid 210 is made of a plate-shaped member having a rectangular shape in plain view. A back surface 210a (−Y-side surface) of the lid 210 has a bonding portion bonded to the base 220. The bonding portion has a sufficient flatness appropriate for bonding by the ion-beam activation bonding method (typically, average roughness Ra is around 1 nm).

The base 220 is made of a plate-shaped member having a rectangular shape in plain view, and has a depressed portion 221 at the central portion of the front surface side (+Y-side surface) as illustrated in FIG. 5. The depressed portion 221 is surrounded by a bonding surface 220a, which is bonded to the lid 210. Bonding the lid 210 and the base 220 forms a cavity 240 (housing space), which houses the piezoelectric vibrating piece 130. Note that the bonding surface 220a has a sufficient flatness appropriate for bonding by the ion-beam activation bonding method (typically, average roughness Ra is around 1 nm).

A connecting electrode 222 is formed in the depressed portion 221 of the base 220, and an external electrode 224 is formed on the back surface of the base 220. A through hole 225 that penetrates the base 220 in the Y direction is formed. The through hole 225 includes a through electrode 226 that electrically connects the connecting electrode 222 and the external electrode 224. In addition, a dummy electrode 224a is formed on the back surface of the base 220. Note that the connecting electrode 222, the external electrode 224, and the through electrode 226 are approximately similar to those of the piezoelectric device 100 of the first embodiment.

Similar to the first embodiment, the exposed portion of the piezoelectric vibrating piece 130 and the conductive adhesive 150 are coated by the coating layers 141, 141f. Furthermore, the front surface (the exposed portion) of the base 220 is coated by the coating layer 242. The material and similar condition of the coating layer 242 are similar to those of the coating layer 142 of the first embodiment.

Thus, according to the piezoelectric device 200, since the piezoelectric vibrating piece 130 similar to that of the first embodiment is used, the excitation electrodes 131 and 132 are coated by the coating layer 141 so as to prevent the damage and similar failures of the excitation electrodes 131 and 132, thus improving the reliability. Also, on the base 220, the coating layer 242 prevents the damage and similar failures of the connecting electrode 222. In addition, the fabrication method of the piezoelectric device 200 is approximately similar to the fabrication method of the piezoelectric device 100 except for that the depressed portion is not formed on the lid 210, but the depressed portion 221 is formed on the base 220. Accordingly, the fabrication method of the piezoelectric device 200 allows preventing the excitation electrode 131 and similar electrode from being etched carelessly and allows reducing the variation of the resonance frequency of the piezoelectric vibrating piece 130 to prevent the production of inferior products.

### Configuration of Piezoelectric Device 300 According to Third Embodiment

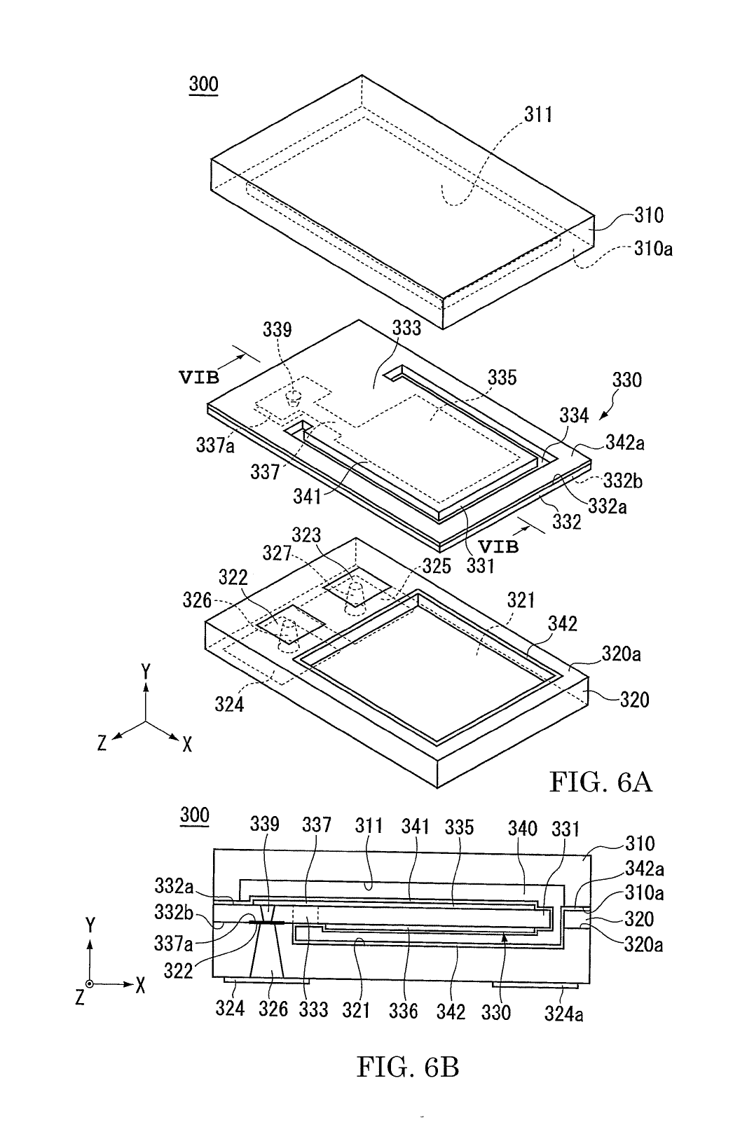

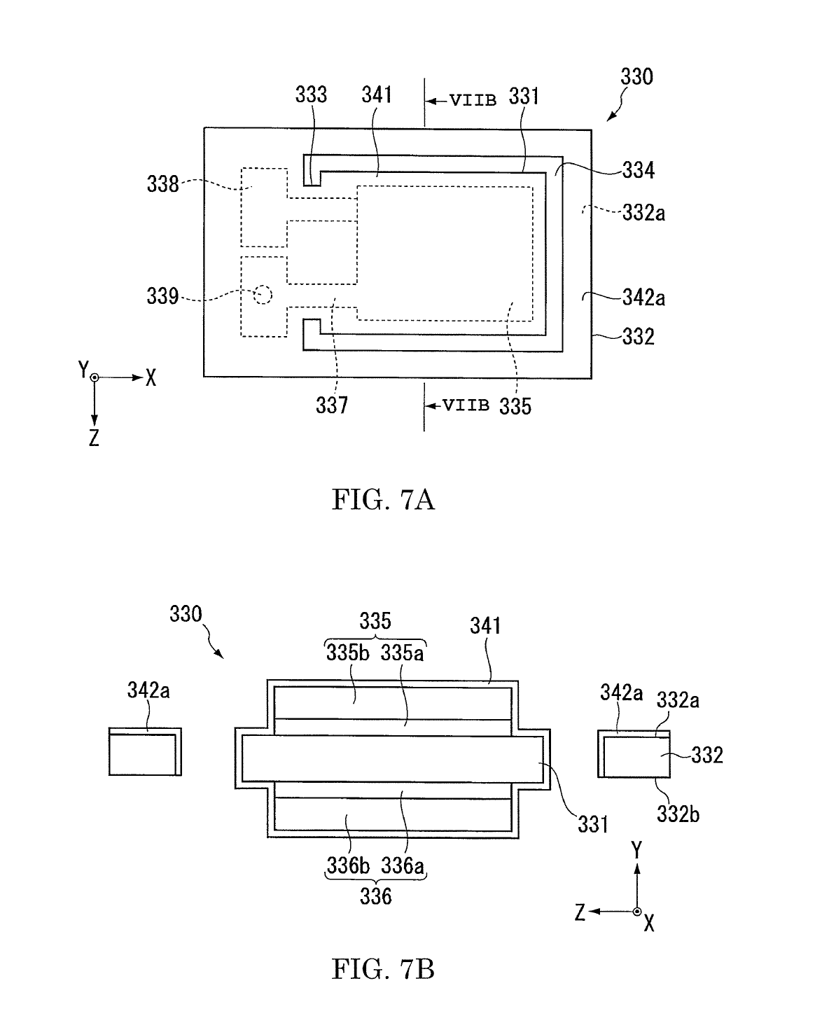

The following describes a piezoelectric device 300 according to the third embodiment with reference to FIG. 6A, FIG. 6B, FIG. 7A, and FIG. 7B. As illustrated in FIG. 6A, the piezoelectric device 300 includes a lid 310 and a base 320, which sandwich a piezoelectric vibrating piece 330. The lid 310 is bonded to the +Y-side of the piezoelectric vibrating piece 330, while the base 320 is bonded to the −Y-side of the piezoelectric vibrating piece 330. Similar to the first and second embodiments, the lid 310 and the base 320 are made of, for example, a borosilicate glass.

As illustrated in FIG. 6A and FIG. 6B, the lid 310 is formed in a rectangular plate-shape, and has a depressed portion 311 and a bonding surface 310a on the back surface (−Y-side surface). The bonding surface 310a surrounds the depressed portion 311. The bonding surface 310a is bonded to a front surface 332a (+Y-side surface) of a framing portion 332 of the piezoelectric vibrating piece 330 described below. The bonding surface 310a is directly bonded to the front surface 332a. Note that the bonding surface 310a and front surface 332a have a sufficient flatness appropriate for bonding by the ion-beam activation bonding method (typically, average roughness Ra is around 1 nm).

The base 320 is also formed in a rectangular plate-shape, and has a depressed portion 321 and a bonding surface 320a on the front surface (+Y-side surface). The bonding surface 320a surrounds the depressed portion 321. The bonding surface 320a faces a back surface 332b (−Y-side surface) of the framing portion 332 of the piezoelectric vibrating piece 330. As illustrated in FIG. 6B, the base 320 is bonded to the back surface side (−Y-side surface side) of the piezoelectric vibrating piece 330 by a bonding material (not illustrated) disposed between the bonding surface 320a and the back surface 332b of the framing portion 332. Besides the bonding surface 320a and the back surface 332b are bonded to each other directly, the bonding surface 320a and the back surface 332b may be bonded using a bonding material such as a low melting point glass or a polyimide.

As illustrated in FIG. 6A, at the −X side region of the front surface of the base 320, connecting electrodes 322 and 323 are formed, while at the −X side region of the back surface of the base 320, external electrodes 324 and 325 are formed. In addition, the base 320 includes through electrodes 326 and 327 that penetrate the base 320 in the Y direction. The through electrode 326 electrically connects the connecting electrode 322 and the external electrode 324, while the through electrode 327 electrically connects the connecting electrode 323 and the external electrode 325. Note that, as illustrated in FIG. 6B, at the +X side region of the back surface of the base 320, dummy electrodes 324a are formed.

The connecting electrodes 322 and 323, the external electrodes 324 and 325, and the through electrodes 326 and 327 are made of a metal similar to the metal used for those of the first and second embodiments. In addition, connecting between the connecting electrode 322 and the external electrode 324 is not limited to the through electrode 326, and similarly connecting between the connecting electrode 323 and the external electrode 325 is not limited to the through electrode 327. For example, at the corners or the sides of the base 320, cutouts (castellations) may be formed, and then the connecting electrodes 322 and 323, and the external electrodes 324 and 325 may be connected to each other by electrodes formed at the cutouts.

Similar to the first and second embodiments, for example, an AT-cut quartz-crystal material is used as the piezoelectric vibrating piece 330. As illustrated in FIG. 7A, the piezoelectric vibrating piece 330 includes a vibrating portion 331, the framing portion 332, and an anchor portion 333. The vibrating portion 331 vibrates at a predetermined vibration frequency, the framing portion 332 surrounds the vibrating portion 331, and the anchor portion 333 connects the vibrating portion 331 and the framing portion 332. Between the vibrating portion 331 and the framing portion 332, a through hole 334 is formed to penetrate the piezoelectric vibrating piece 330 in the Y-axis direction except for the anchor portion 333.

The vibrating portion 331 has a rectangular shape, and the thickness of the vibrating portion 331 in the Y-axis direction is the same as that of the framing portion 332. The thickness of the vibrating portion 331 may be thinner than that of the framing portion 332. Also, the vibrating portion 331 may have a mesa shape where the central portion is thicker than the peripheral portion. The framing portion 332 has a rectangular shape surrounding the vibrating portion 331, and the front surface 332a and back surface 332b of the framing portion 332 are respectively bonded to the bonding surface 310a of the lid 310 and the bonding surface 320a of the base 320.

On the front surface of the vibrating portion 331, an excitation electrode 335 is formed. From the excitation electrode 335, an extraction electrode 337 is formed to extend in the −X direction to the front surface of the anchor portion 333 and framing portion 332. Furthermore, the extraction electrode 337 is connected to an extraction electrode 337a formed on the back surface of the framing portion 332 via a through electrode 339 that penetrates the framing portion 332 in the Y direction. On the back surface of the vibrating portion 331, an excitation electrode 336 is formed. From the excitation electrode 336, an extraction electrode 338 is formed to extend in the −X direction to the back surface of the anchor portion 333 and framing portion 332.

As illustrated in FIG. 7B, the excitation electrodes 335 and 336, extraction electrodes 337 and 338, and similar electrodes have a two-layered structure including base layers 335a and 336a made of, for example, a nickel-tungsten for increasing adhesion with a quartz-crystal material, and main electrode layers 335b and 336b such as a gold. Metals used as the base layer 335a and similar layer and metals used as the main electrode layer 335b and similar electrode are similar to the metals used as those of the first and second embodiments.

As illustrated in FIG. 7B, on the piezoelectric vibrating piece 330, a coating layer 341 is coated so as to cover the exposed portion that includes the excitation electrodes 335 and 336 and the extraction electrodes 337. Also, the depressed portion 321 of the base 320 is coated by a coating layer 342, but it is optional that whether or not the depressed portion 321 is coated by the coating layer 342. In addition, the side surfaces of the framing portion 332 of the piezoelectric vibrating piece 330, and the side surfaces and bottom surface of the base 320 may be coated by the coating layer 342. While the film thickness of the coating layers 341 and 342 is not specifically limited, the film thickness is set to from several nm to several 10 s of nm.

The coating layers 341 and 342 include an insulator or dielectric, and the sputtering rate of the insulator or dielectric is lower than that of the metal used as the main electrode layers 335b and 336b of the excitation electrodes 335 and 336. Examples of the insulators or dielectrics used as the coating layers 341 and 342 include an aluminum oxide and an aluminum nitride, which are similar to the materials used as those of the first and second embodiments.

As illustrated in FIG. 6A and FIG. 6B, in the piezoelectric vibrating piece 330, the front surface 332a of the framing portion 332 of the piezoelectric vibrating piece 330 is directly bonded to the bonding surface 310a of the lid 310. Also, the back surface 332b of the framing portion 332 of the piezoelectric vibrating piece 330 is bonded to the bonding surface 320a of the base 320. The back surface 332b and the bonding surface 320a may be bonded directly or may be bonded using a bonding material. Bonding the piezoelectric vibrating piece 330 to the base 320 makes an electrical connection between the extraction electrodes 337a and 338 and between the connecting electrodes 322 and 323. Note that the extraction electrodes 337a and 338 and the connecting electrodes 322 and 323 may be connected via conductive adhesives. Bonding the lid 310 and base 320 to the piezoelectric vibrating piece 330 makes a cavity 340 that houses the vibrating portion 331 of the piezoelectric vibrating piece 330. The inside of the cavity 340 is sealed under a vacuum atmosphere or an inert gas atmosphere such as a nitrogen gas.

Thus, according to the piezoelectric device 300, the coating layer 341 is formed on the exposed portion including the excitation electrodes 335 and 336. Accordingly, the excitation electrodes 335 and 336 are coated by the coating layer 341 that has a low sputtering rate by which the damage and similar failures of the excitation electrodes 335 and 336 can be prevented, thus improving the reliability.

Fabricating Method of Piezoelectric Device 300

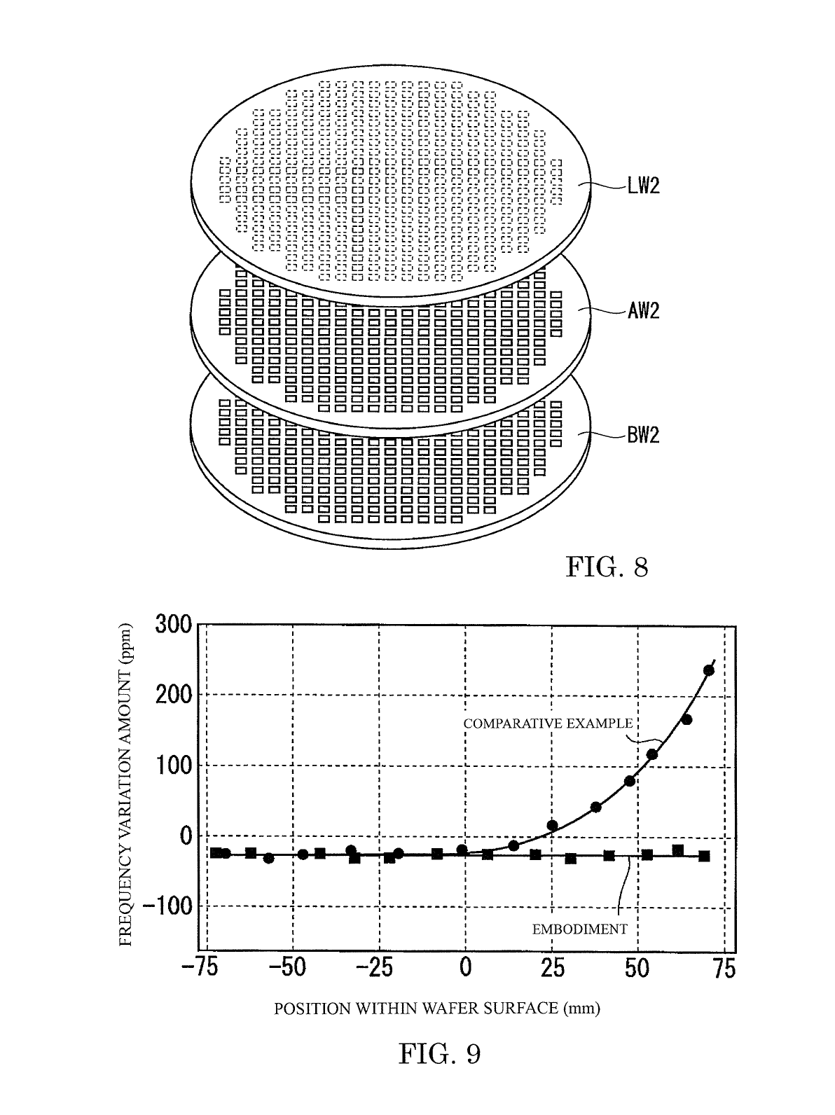

The following describes a method for fabricating the piezoelectric device 300 with reference to FIG. 8. Similar to the above-described piezoelectric device 100, the piezoelectric device 300 is fabricated using the wafer level packaging method. The multiple patterning is performed on respective wafers of the lid 310, the base 320, and the piezoelectric vibrating piece 330 from which individual pieces are cut out. For example, a borosilicate glass is used as a lid wafer LW2 and as a base wafer BW2. A crystal wafer cut out from a crystalline body by the AT-cut method is used as a piezoelectric wafer AW2.

On the lid wafer LW2, the depressed portion 311 is formed by sand-blasting or wet etching. On the other hand, on the base wafer BW2, the depressed portion 321 and through holes are formed by sand-blasting or wet etching. On the base wafer BW2, the through electrodes 326 and 327 are formed by, for example, copper plating. The connecting electrodes 322 and 323 are formed on the front surface of the base wafer BW2, while the external electrodes 324 and 325 are formed on the back surface of the base wafer BW2 such that the connecting electrodes 322 and 323, and the external electrodes 324 and 325 are electrically connected to the through electrodes 326 and 327. Dummy electrodes 324a are formed at the same time. The connecting electrodes 322 and 323 and external electrodes 324 and 325 are formed by depositing a gold or a silver on the base layer made of, for example, a nickel-tungsten by sputtering or vacuum evaporation using, for example, a metal mask stencil.

The piezoelectric wafer AW2 is adjusted by, for example, etching or cutting such that the thickness (the width of the Y-axis direction) of the wafer is decreased. Note that a mesa shape, where the central portion of the vibrating portion 331 is thicker than the peripheral portion, may be formed by, for example, the photolithography and etching. Next, the excitation electrodes 335 and 336 are respectively formed on the front surface and back surface of the vibrating portion 331. The excitation electrodes 335 and 336 are formed as follows: the base layers 335a and 336a of a nickel-chrome alloy or similar material are formed by sputtering or vacuum evaporation using a metal mask stencil; and the main electrode layers 335b and 336b of a gold or similar material are formed on the base layers 335a and 336a. Note that the excitation electrodes 335 and 336 may be patterned by, for example, the photolithography and etching instead of using a metal mask stencil.

The extraction electrodes 337, 337a, and 338 are formed at the same time when the excitation electrodes 335 and 336 are formed. The through electrode 339 is formed by filling the through hole with copper plating before the extraction electrodes 337, 337a, and 338 are formed. Note that the through electrode 339 is not limited to be formed by filling the through hole with copper plating, but may be formed by forming a conductive metal film on the wall surface of the through hole.

Next, the base wafer BW2 is bonded to the back surface of the piezoelectric wafer AW2. At that time, the bonding surface 320a of the base 320 is bonded to a back surface of a region that subsequently become the framing portion 332 of the piezoelectric vibrating piece 330 (base bonding process). Note that both wafers are bonded to each other by not only the ion-beam activation bonding method using the ion beam activation bonding apparatus 10 shown in FIG. 4 but also various bonding methods, for example, a bonding method using a bonding material such as a low melting point glass and a polyimide. When the base wafer BW2 is bonded to the piezoelectric wafer AW2, the connecting electrodes 322 and 323 are electrically connected to the extraction electrodes 337a and 338.

Next, a part of the piezoelectric wafer AW2 is penetrated in the Y direction to be a through hole 334 by, for example, wet etching. This forms the piezoelectric vibrating pieces 330 on the piezoelectric wafer AW2. The piezoelectric vibrating piece 330 includes the vibrating portion 331, the framing portion 332 surrounding the vibrating portion 331, and the anchor portion 333 connecting the vibrating portion 331 and the framing portion 332. While the through hole 334 is formed after the base wafer BW2 is the bonded to the piezoelectric wafer AW2, the through hole 334 may be formed before the bonding.

Next, the coating layers 341 and 342 of an insulator or dielectric are formed on the exposed portions of the piezoelectric vibrating piece 330 and base 320 (coating process). Similar to the first embodiment, for the coating process, the atomic layer deposition (ALD) method is used. Use of the ALD allows precisely predicting a frequency deviation due to the film formation on the piezoelectric vibrating piece 330. While the film thickness of the coating layers 341 and 342 is not specifically limited, the film thickness of the coating layers 341 and 342 is set to be about 1 nm to several 10 nm to provide the thickness to the extent that the coating layers do not dissipate by the ion radiation, while so as not to make the frequency variation caused by forming the insulator or dielectric layers large.

Next, the lid wafer LW2 is bonded to the front surface of the piezoelectric wafer AW2 by the ion-beam activation bonding method (lid bonding process). Similar to the first embodiment, the ion-beam activation bonding method is performed using the ion beam activation bonding apparatus 10 shown in FIG. 4. The lid wafer LW2 is held on the wafer holder of the pressure applying mechanism 40, while the piezoelectric wafer AW2 (the back surface is already bonded to the base wafer BW2) is held on the wafer holder of the alignment stage 30. The lid wafer LW2 and the piezoelectric wafer AW2 are opposed to each other. Next, the inside of the vacuum chamber 20 is evacuated, and then an argon beam IB is irradiated to both wafers from the ion source 50.

The surfaces of the lid wafer LW2 and base wafer AW2 are sputter etched to be removed contamination by the argon beam IB. Note that similar to the first embodiment, an iron, a chrome, an aluminum and a similar metal are deposited on the piezoelectric wafer AW2 and similar wafer. Accordingly, the coating layers 341 and 342 become in a state where an iron, a chrome, an aluminum, or and similar elements are mixed to an insulator film or dielectric film, or in a state of a layered film of an insulator film or similar film and an iron, a chrome, an aluminum, and similar elements. Note that, similar to the first embodiment, since the coating layer 341 has a sputtering rate lower than that of the excitation electrode 335 and similar electrode, the excitation electrodes 335 and 336 are not etched carelessly by the irradiation of the argon beam IB.

Next, after the argon beam IB is irradiated for the predetermined time period, the lid wafer LW2 and piezoelectric wafer AW2 are aligned to each other, then both wafers are bonded with the condition of the predetermined pressure and press-contact time by the pressure applying mechanism 40. Afterwards, the bonded wafer is removed from the ion beam activation bonding apparatus 10, and is diced along the scribe line to complete individual piezoelectric devices 300.

Thus, similar to the first embodiment, the fabrication method of the piezoelectric device 300 allows preventing the excitation electrode 335 and similar electrodes from being etched carelessly, and reducing the variation of the resonance frequency of the piezoelectric vibrating piece 330, so as to prevent the production of inferior products. In addition, similar to the first embodiment, adjusting the resonance frequencies with considering the amount of deposited metals when the ion-beam activation bonding method is performed allows producing, with high production yield, the piezoelectric devices 300 having the desired resonance frequency after are the bonding of the wafers by wafer level packaging using glass.

Although the embodiments are described above, this disclosure is not limited to the above-described explanations, and various kinds of modifications can be made without departing the scope of the disclosure. For example, a tuning-fork type piezoelectric vibrating piece (quartz-crystal vibrating piece) may be used instead of the piezoelectric vibrating piece 130 or similar piece. In addition, the piezoelectric vibrating piece 130 or similar piece is not limited to a quartz-crystal vibrating piece, but any other piezoelectric materials such as a lithium tantalate and a lithium niobate can be used. Also, a Micro Electro Mechanical Systems (MEMS) device or similar device, where silicon wafers are used, may be used instead of the piezoelectric vibrating piece 130 or similar piece.

In addition, the piezoelectric device is not limited to be a piezoelectric resonator (crystal resonator) but may be an oscillator. In the case of the oscillator, for example, the oscillator includes an Integrated Circuit (IC) and is electrically connected to the piezoelectric vibrating piece 130 or similar member. Furthermore, an AT-cut crystal wafer may be used as the lid wafers LW1 and LW2 and as the base wafers BW1 and BW2. In addition, not only the ALD method but also any other methods such as an evaporation may be used for forming the coating layers 141 and 341 and similar layers.

### Working Example

The following describes a working example. As the working example, a 26 MHz crystal resonator (piezoelectric device 100) having a glass package structure shown in FIG. 1B was used. An AT-cut quartz-crystal vibrating piece was used as the piezoelectric vibrating piece. The excitation electrodes 131 and 132 were formed of: chrome layers (30 nm) as the base layers 131a and 132a; and silver layers (150 nm) as the main electrode layers 131b and 132b. Aluminum oxide layers (2 nm) were formed as the coating layers 141, 141f, and 142 by the ALD method, namely trimethylaluminium (TMA) and H₂O are alternately supplied in a pulsed manner for 20 cycles. As illustrated in FIG. 3A and FIG. 3B, the quartz-crystal vibrating piece was mounted on a 6-inch base wafer BW1 by a conductive paste, and then the base wafer BW1 was bonded to a 6-inch lid wafer LW1 by the ion beam activation bonding apparatus 10 shown in FIG. 4 to fabricate the 26 MHz crystal resonator.

As a comparative example, a 26 MHz AT-cut crystal resonator having excitation electrodes was used, without coating layers. The excitation electrodes formed of chrome layers (30 nm) (base layers) and silver layers (150 nm) (main electrode layers) were fabricated through the same fabrication process as the working example. Note that the electrode materials were formed by an electron-beam evaporation method.

The frequency variation amounts between before and after the bonding of the base wafer BW1 and the lid wafer LW1 were measured, and then the distributions of the frequency variation amounts within the wafer surfaces were compared for the working example and the comparative example. Note that, in each case, frequency adjustment was performed when the quartz-crystal vibrating piece was mounted on the base wafer BW1, and then both frequencies within the surfaces were set to 26 MHz. FIG. 9 is a diagram plotting the fluctuation of the frequency variation amounts along the direction parallel to the central axis of the ion source 50 within the 6-inch wafer for the working example and the comparative example. In FIG. 9, the positive direction of the horizontal axis is the side of the ion source 50.

In the working example, the frequency variation is constant and is about −30 ppm at the positions within the wafer surface, while in the comparative example, the frequency variation amount is large and is +250 ppm at the positive side (the side close to the ion source 50) of the horizontal axis. The frequency variation amount decreases as moving toward the center and then approaches −30 ppm as moving from the center of the wafer toward the end in the direction opposite to the ion source 50. A silver is etched more at the side close to the ion source 50 since etching strength of an argon beam is stronger than the deposited metals. Since a silver has a high sputtering rate and a high density, the frequency variation is remarkable. As moving away from the ion source 50 (toward the negative side of the horizontal axis in FIG. 9), the contribution of etching to the frequency variation is gradually decreased, while the contribution of the deposited metals to the frequency variation appears.

In the working example, due to the coating layer 141 and similar layers made of an aluminum oxide, only frequency variation caused by the deposited metals is observed within not only, for example, the main electrode layer 131b made of a silver but also the entire 6-inch wafer since the etching effect to the coating layer 141 and similar layers is extremely small. In the working example, adjusting the frequency to a target frequency +30 ppm in the frequency adjustment process before the bonding of the lid wafer LW1 and the base wafer BW1 allows fabricating a 26 MHz-frequency crystal resonator after the bonding. While an aluminum oxide was used as the coating layer 141 and similar layer in the working example, the similar results were obtained by using an oxide based insulator or an oxide based dielectric such as a silicon oxide, a magnesium oxide, a titanium oxide, and a zirconium oxide; and a nitride based insulator or a nitride based dielectric such as a boron nitride, an aluminum nitride, and a silicon nitride.

This disclosure provides a piezoelectric device that includes a piezoelectric vibrating piece where an electrode is formed. The piezoelectric vibrating piece includes a coating layer that covers an exposed portion of the piezoelectric vibrating piece. The coating layer is formed of an insulator or a dielectric with a sputtering rate lower than a sputtering rate of the electrode.

The piezoelectric device also may include a lid and a base bonded to one another. The piezoelectric vibrating piece may be disposed at a depressed portion formed in at least one of the lid and the base. The lid and the base may be bonded to each other directly. The piezoelectric vibrating piece includes a vibrating portion, a framing portion, and an anchor portion. The framing portion surrounds the vibrating portion. The anchor portion connects the vibrating portion and the framing portion. The piezoelectric vibrating piece includes a lid and a base bonded to respective front surface and back surface of the framing portion. The framing portion and the lid are bonded to each other directly. On an exposed portion of the base, a coating layer of an insulator or a dielectric may be formed. The coating layer can apply an oxide based insulator or dielectric of any of an aluminum oxide (Al₂O₃), a silicon oxide (SiO₂), a magnesium oxide (MgO), a titanium oxide (TiO₂), and a zirconium oxide (ZrO₂). The coating layer can apply a nitride based insulator or dielectric of any of a boron nitride (BN), an aluminum nitride (AlN), and a silicon nitride (SiN).

This disclosure provides a method for fabricating a piezoelectric device including a piezoelectric vibrating piece. The method includes forming a coating layer of an insulator or a dielectric having a sputtering rate lower than a sputtering rate of the electrode so as to cover an exposed portion of the piezoelectric vibrating piece.

The method for fabricating a piezoelectric device may include mounting the piezoelectric vibrating piece on a base and bonding a lid to the base using an ion-beam activation bonding. The coating may be performed after the mounting process. The method for fabricating a piezoelectric device may include bonding a base and bonding a lid. The bonding bonds a base on a back surface of a framing portion. The bonding includes the piezoelectric vibrating piece that includes a vibrating portion, a framing portion, and an anchor portion. The framing portion surrounds the vibrating portion. The anchor portion connects the vibrating portion and the framing portion. The bonding bonds a lid to a surface of the framing portion using an ion-beam activation bonding. The coating may be performed after the bonding a base. The coating may form a coating layer at an exposed portion of the base. The bonding of a lid may be performed under vacuum atmosphere.

According to this disclosure, the first to third embodiments can prevent the damage or similar failures of the electrodes to improve the reliability of the piezoelectric device by coating the electrodes formed on the piezoelectric vibrating piece with the coating layers. Furthermore, even if the ion-beam activation bonding method or any similar bonding method is used for bonding the lid, this disclosure prevents the electrode from being etched carelessly, reduces the variation of the resonance frequency of the piezoelectric vibrating piece, and thus prevents the production of inferior products to improve the production yield.

### Configuration of Piezoelectric Device 100a According to Fourth Embodiment

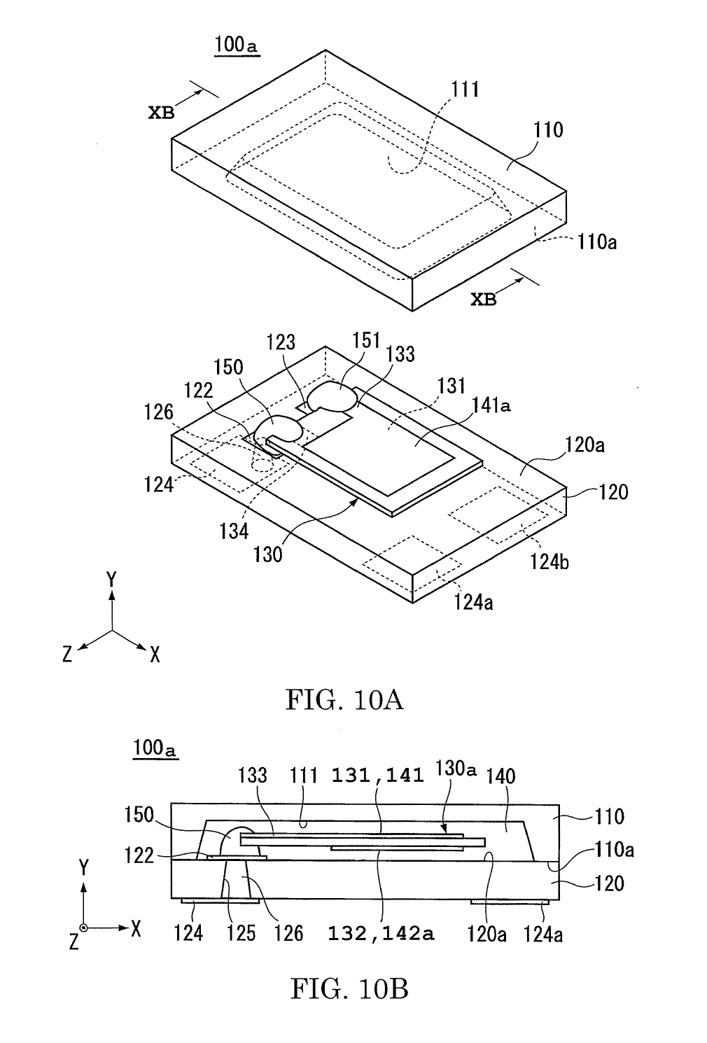

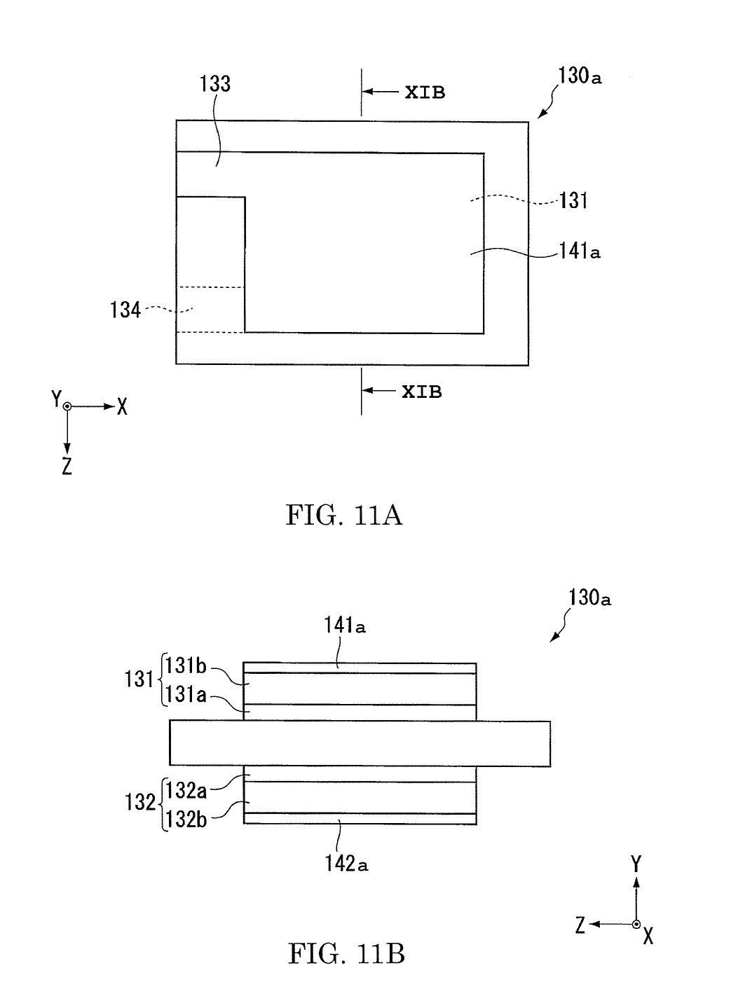

The following describes the fourth embodiment. In the following description, like reference numerals designate identical or corresponding parts of the first embodiment, and therefore such elements will not be further elaborated here. FIG. 10A, FIG. 10B, FIG. 11A, and FIG. 11B illustrate a piezoelectric device 100a according to the fourth embodiment. In addition, FIG. 10B illustrates a cross-sectional view taken along the line corresponding to the line XB-XB of FIG. 10A. The piezoelectric device 100a includes a piezoelectric vibrating piece 130a. The fourth embodiment differs from the first to the third embodiments in a configuration of a coating layer (a cap layer).

On the excitation electrodes 131 and 132, as illustrated in FIG. 11B, cap layers 141a and 142a are formed. The cap layers 141a and 142a serve as a coating layer that coats the respective excitation electrodes 131 and 132. The cap layers 141a and 142a have the approximately same size as the excitation electrodes 131 and 132. However, the cap layers 141a and 142a may be formed at a slightly larger region so as to cover including side surfaces of the excitation electrodes 131 and 132. Furthermore, the cap layers 141a and 142a may be formed on the extraction electrodes 133 and 134. In this case, among the extraction electrodes 133 and 134, the cap layers 141a and 142a may not be formed at regions where conductive adhesives 150 and 151, which will be described later, are applied. While the film thickness of the cap layers 141a and 142a is not specifically limited, the film thickness is set to from several nm to several 10 nm.

The cap layers 141a and 142a include a conductive oxide or conductive nitride, and the sputtering rate of the conductive oxide and the conductive nitride is lower than that of the metal used as the main electrode layers 131b and 132b of the excitation electrodes 131 and 132. As for the conductive oxide, any one of indium oxide (In₂O₃), tin oxide (SnO₂), ruthenium oxide (RuO₂), and titanium oxide (TiO₂) is used. Here, the material other than titanium oxide has a conductive property in ordinary film forming conditions. Regarding the titanium oxide, film formation under conditions in which oxygen defect is likely to occur (a state of less oxygen) ensures a conductive property.

As a conductive oxide used for the cap layers 141a and 142a, any one of indium oxide (In₂O₃) to which tin (Sn) is doped, tin oxide (SnO₂) to which antimony (Sb) is doped, titanium oxide (TiO₂) to which aluminum (Al) is doped, and zinc oxide (ZnO) to which any one of indium (In), gallium (Ga), and aluminum (Al) is doped may be used. Among them, regarding indium oxide, tin oxide, and titanium oxide, carrier density can be increased by doping to decrease a resistance value from a resistance value in a non-doped state. Here, doping also includes a meaning of simply sputtering a target including a doping element in addition to a process such as ion implantation. If not doped, zinc oxide is an insulator. Regarding titanium oxide, as a method other than doping, a resistance value may be decreased by reduction treatment (H₂ annealing).

As a conductive nitride used for the cap layers 141a and 142a, any one of hafnium nitride (HfN), tantalum nitride (TiN), tantalum nitride (TaN), tungsten nitride (WN), and zirconium nitride (ZrN) may be used. These nitride have a conductive property in ordinary film formation, thus special treatment is unnecessary.

The following is the sputter etching effects by the irradiation of argon ion beam (argon beam). When an ion beam is vertically irradiated, assuming that the sputtering rate of silver is normalized to 1, a sputtering rate of gold is 0.71. Then, a sputtering rate of indium oxide, tin oxide, ruthenium oxide, titanium oxide, indium oxide to which tin is doped, tin oxide to which antimony is doped, titanium oxide to which aluminum is doped, zinc oxide to which any one of indium, gallium, or aluminum is doped, hafnium nitride, titanium nitride, tantalum nitride, tungsten nitride, and zirconium nitride, is 0.2 to 0.3. All the materials have a lower sputtering rate than the sputtering rates of gold and silver of the main electrode layers 131b and 132b.

Note that the amount of frequency variation due to the sputtering of the excitation electrodes 131 and 132 is proportional to the etched mass of the excitation electrodes 131 and 132 by sputtering. Accordingly, since the density of for example, titanium oxide, titanium oxide in which aluminum is doped, or titanium nitride is low, and therefore the multiplication of the sputtering rate and the density of the titanium oxide, the aluminum doped titanium oxide, or the titanium oxide is a low value so that using the titanium oxide, the aluminum doped titanium oxide, or the titanium oxide as the cap layers 141a and 142a would advantageously allow the amount of frequency variation to decrease.

As illustrated in FIG. 10A and FIG. 10B, the piezoelectric vibrating piece 130a is supported on the front surface 120a of the base 120 by the conductive adhesives 150 and 151. The extraction electrode 134 and connecting electrode 122 are electrically connected via the conductive adhesive 150, while the extraction electrode 133 and the connecting electrode 123 are electrically connected via the conductive adhesive 151. Then, the lid 110 and the base 120 are bonded to each other. Accordingly, the piezoelectric vibrating piece 130a is housed in the cavity 140. The inside of the cavity 140 is sealed under a vacuum atmosphere or an inert gas atmosphere of, for example, a nitrogen gas. Note that the bonding surface 110a of the lid 110 and the front surface 120a of the base 120 are directly bonded to each other without, for example, a bonding material.

Thus, according to the piezoelectric device 100a, since the cap layers 141a and 142a are formed on the excitation electrodes 131 and 132, the excitation electrodes 131 and 132 are coated by the cap layers 141a and 142a whose sputtering rate is low. This can prevent the damage and similar failures of the excitation electrodes 131 and 132, thus improving the reliability of the piezoelectric device 100a.

### Fabricating Method of Piezoelectric Device 100a

The method for fabricating the piezoelectric device 100a according to the fourth embodiment differs from the first to the third embodiments. They differ in a formation process of the coating layers (the cap layers) 141a and 142a in the following point. The cap layers 141a and 142a are formed on the excitation electrodes 131 and 132. The cap layers 141a and 142a are formed by, for example, sputtering or vacuum evaporation using a metal mask stencil, photolithography, and etching. Then, a film of conductive oxide or conductive nitride with a lower sputtering rate than the sputtering rate of the excitation electrodes 131 or a similar electrode is formed. Thus, the cap layers 141a and 142a are formed (a cap formation process). A process of doping tin after film formation of indium oxide, a process of doping antimony after film formation of tin oxide, a process of doping aluminum after film formation of titanium oxide, and a process of doping any one of indium, gallium, and aluminum after film formation of zinc oxide may be performed. This doping is performed by simply sputtering a target including a doping element. Regarding titanium oxide, instead of doping of aluminum, reduction treatment (H₂ annealing) may be performed. After the cap layers 141a and 142a are formed, the piezoelectric wafer AW1 is diced along the scribe line. Accordingly, the individual piezoelectric vibrating pieces 130a are completed.

On the other hand, similar to the first to the third embodiments, the surfaces of the lid wafer LW1 and base wafer BW1 are sputter etched to be removed contamination by the argon beam IB. At this time, the members of the ion source 50 such as an anode, which are exposed to the argon plasma, are sputtered. Accordingly, the argon beam IB irradiated from the ion source 50 includes an iron and a chrome, which are components of a stainless steel of which the ion source 50 is made. In addition, since the argon beam IB irradiated from the ion source 50 has a large divergence angle, the argon beam IB sputters not only the lid wafer LW1 and a similar wafer but also the stainless steel of the inner wall in the vacuum chamber 20 and other components that are made of aluminum alloy. This makes an iron, a chrome, an aluminum, and similar elements deposited on the lid wafer LW1 and similar wafer. Namely, etching and deposition are carried out simultaneously on the surfaces of the lid wafer LW1 and the base wafer BW1. Accordingly, the cap layers 141a and 142a become in a state where an iron, a chrome, an aluminum, or similar element are mixed to a conductive oxide or conductive nitride, or in a state of a layered film of a conductive oxide or conductive nitride and an iron, a chrome, an aluminum, or similar element.

As described above, the cap layers 141a and 142a formed on the excitation electrodes 131 and 132 of the piezoelectric vibrating piece 130a have a sputtering rate lower than that of a gold or a silver used as the excitation electrode 131 and similar electrode. Accordingly, the excitation electrodes 131 and 132 are not etched carelessly by the irradiation of the argon beam IB since they are coated by the cap layers 141a and 142a.

On the other hand, the cap layers 141a and 142a have a low sputtering rate, as well as the argon beam TB is irradiated to the cap layers 141a and 142a from the direction inclined by approximately 90 degree with respect to the vertical direction of the lid wafer LW and similar wafer as illustrated in FIG. 4, accordingly, the actual sputtering rate is significantly low. Consequently, the cap layers 141a and 142a are hardly etched, and only metal elements such as an iron, a chrome, or an aluminum are deposited on the cap layers 141a and 142a.

Thus, the fabrication method of the piezoelectric device 100a allows preventing the excitation electrode 131 and similar electrode of the piezoelectric vibrating piece 130a from being etched carelessly and reduces the variation of the resonance frequency of the piezoelectric vibrating piece 130a to prevent the production of inferior products.

### Fifth Embodiment

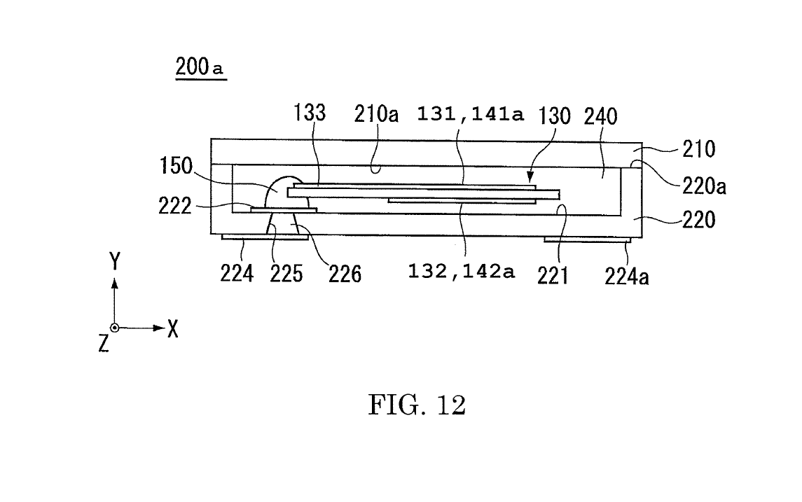

The following describes the fifth embodiment. In the following description, like reference numerals designate identical or corresponding parts of the fourth embodiment, and therefore such elements will not be further elaborated here. FIG. 12 illustrates a piezoelectric device 200a according to the fifth embodiment. In addition, FIG. 12 illustrates a cross-sectional view taken along the line corresponding to the line XB-XB of FIG. 10A. The piezoelectric device 200a includes a piezoelectric vibrating piece 130a similar to the first embodiment.

The piezoelectric device 200a includes a lid 210 and a base 220. As illustrated in FIG. 12, the lid 210 is made of a plate-shaped member having a rectangular shape in plain view. The back surface 210a (−Y-side surface) of the lid 210 has a bonding portion bonded to the base 220. The bonding portion has a sufficient flatness appropriate for bonding by the ion-beam activation bonding method (typically, average roughness Ra is around 1 nm).

The base 220 is a plate-shaped member having a rectangular shape in plan view, and has a depressed portion 221 at the central portion of the front surface side (+Y-side surface) as illustrated in FIG. 12. The depressed portion 221 is surrounded by a bonding surface 220a, which is bonded to the lid 210. Bonding the lid 210 and the base 220 forms a cavity 240 (housing space) which houses the piezoelectric vibrating piece 130a. Note that the bonding surface 220a has a sufficient flatness appropriate for bonding by the ion-beam activation bonding method (typically, average roughness Ra is around 1 nm).

A connecting electrode 222 is formed in the depressed portion 221 of the base 220, and an external electrode 224 is formed on the back surface of the base 220. A through hole 225 that penetrates the base 220 in the Y direction is formed. The through hole 225 includes a through electrode 226 that electrically connects the connecting electrode 222 and the external electrode 224. In addition, a dummy electrode 224a is formed on the back surface of the base 220. Note that the connecting electrode 222, the external electrode 224, and the through electrode 226 are approximately similar to those of the piezoelectric device 100a of the fourth embodiment.

Thus, according to the piezoelectric device 200a, since the piezoelectric vibrating piece 130a similar to that of the first embodiment is used, the excitation electrodes 131 and 132 are coated by the cap layers 141a and 142a so as to prevent the damage and similar failures of the excitation electrodes 131 and 132, thus improving the reliability. The fabrication method of the piezoelectric device 200a is approximately similar to the fabrication method of the piezoelectric device 100a except for that the depressed portion is not formed on the lid 210, but the depressed portion 221 is formed on the base 220. Accordingly, the fabrication method of the piezoelectric device 200 allows preventing the excitation electrode 131 and similar electrode from being etched carelessly and reduces the variation of the resonance frequency of the piezoelectric vibrating piece 130a to prevent the production of inferior products.

### Configuration of Piezoelectric Device 300a According to Sixth Embodiment

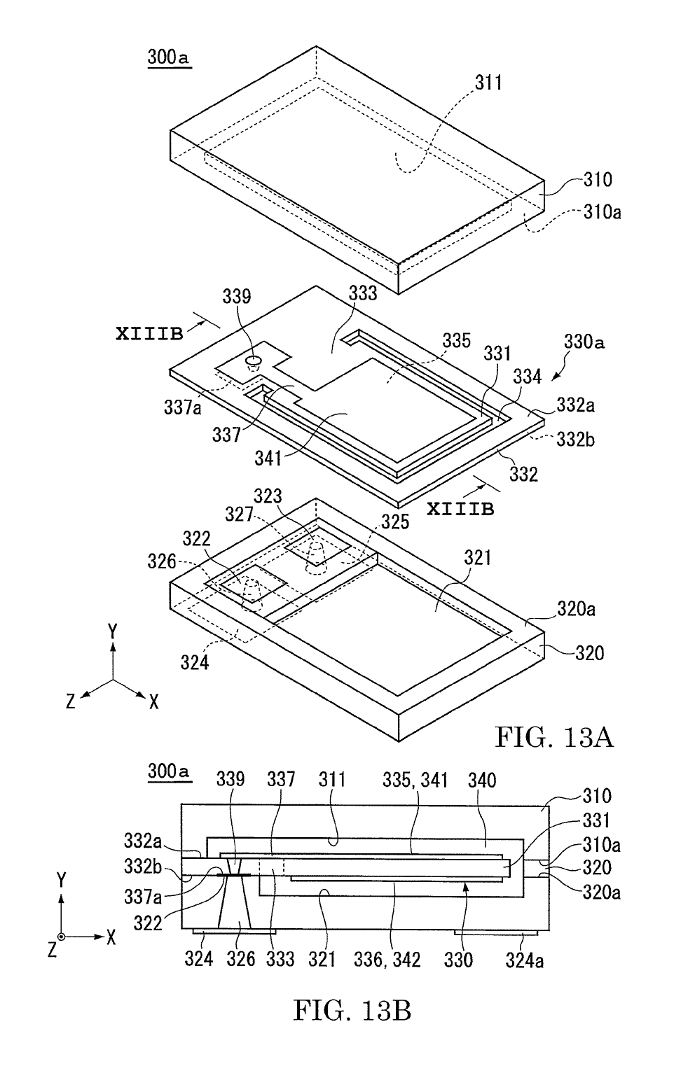

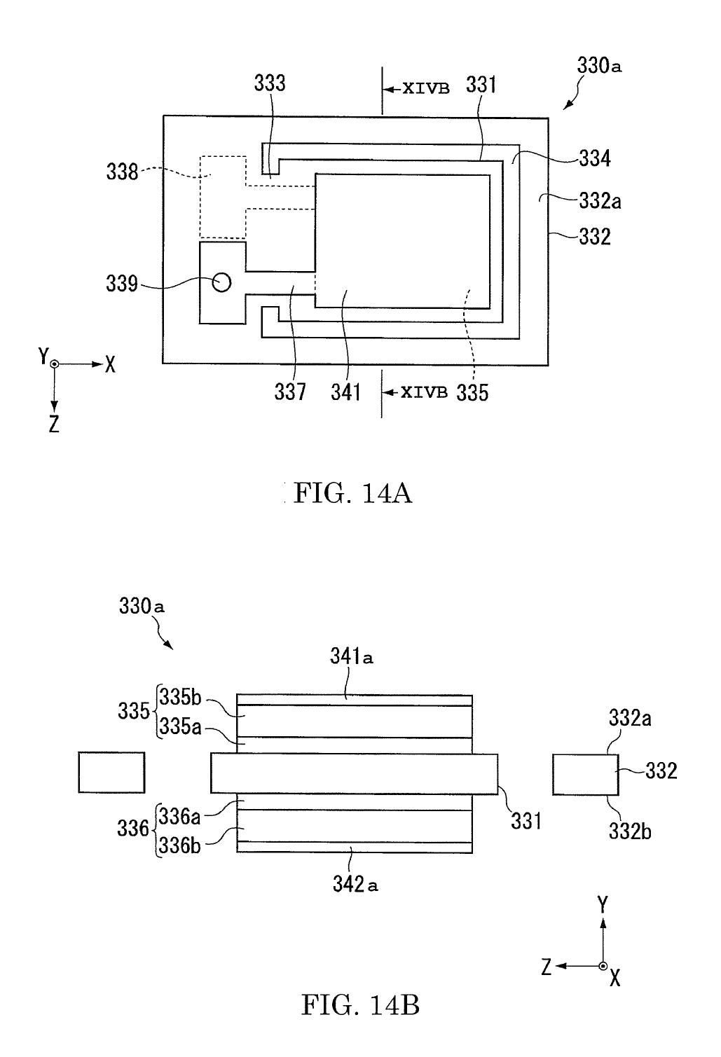

The following describes a piezoelectric device 300a according to the sixth embodiment with reference to FIG. 13A, FIG. 13B, FIG. 14A, and FIG. 14B. As illustrated in FIG. 13A, the piezoelectric device 300a includes a lid 310 and a base 320, which sandwich a piezoelectric vibrating piece 330. The lid 310 is bonded to the +Y-side of the piezoelectric vibrating piece 330, while the base 320 is bonded to the −Y-side of the piezoelectric vibrating piece 330. Similar to the fourth and fifth embodiments, the lid 310 and the base 320 are made of, for example, a borosilicate glass.

As illustrated in FIG. 13A and FIG. 13B, the lid 310 is formed in a rectangular plate-shape and has a depressed portion 311 and a bonding surface 310a on the back surface (−Y-side surface). The bonding surface 310a surrounds the depressed portion 311. The bonding surface 310a is bonded to a front surface 332a (+Y-side surface) of a framing portion 332 of the piezoelectric vibrating piece 330 described below. The bonding surface 310a is directly bonded to the front surface 332a. Note that the bonding surface 310a and front surface 332a have a sufficient flatness appropriate for bonding by the ion-beam activation bonding method (typically, average roughness Ra is around 1 nm).

The base 320 is also formed in a rectangular plate-shape and has a depressed portion 321 and a bonding surface 320a on the front surface (+Y-side surface). The bonding surface 320a surrounds the depressed portion 321. The bonding surface 320a faces a back surface 332b (−Y-side surface) of the framing portion 332 of the piezoelectric vibrating piece 330. As illustrated in FIG. 13B, the base 320 is bonded to the back surface (−Y-side surface side) side of the piezoelectric vibrating piece 330a by a bonding material (not illustrated) disposed between the bonding surface 320a and the back surface 332b of the framing portion 332. Besides the bonding surface 320a and the back surface 332b are bonded to each other directly, and the bonding surface 320a and the back surface 332b may be bonded using a bonding material such as a low melting point glass or a polyimide.

As illustrated in FIG. 13A and FIG. 13B, at the −X side region of the front surface of the base 320, connecting electrodes 322 and 323 are formed, while at the −X side region of the back surface of the base 320, external electrodes 324 and 325 are formed. In addition, the base 320 includes through electrodes 326 and 327 that penetrate the base 320 in the Y direction. The through electrode 326 electrically connects the connecting electrode 322 and the external electrode 324, while the through electrode 327 electrically connects the connecting electrode 323 and the external electrode 325. Note that, as illustrated in FIG. 13B, at the +X side region of the back surface of the base 320, dummy electrodes 324a are formed.

The connecting electrodes 322 and 323, the external electrodes 324 and 325, and the through electrodes 326 and 327 are made of a metal similar to the metal used for those of the first and second embodiments. In addition, connecting means between: the connecting electrodes 322 and 323; and the external electrodes 324 and 325 is not limited to the through electrodes 326 and 327. For example, at the corners or the sides of the base 320, cutouts (castellations) may be formed, and then the connecting electrodes 322 and 323 and the external electrodes 324 and 325 may be connected to each other by electrodes formed at the cutouts.

Similar to the fourth and fifth embodiments, for example, an AT-cut quartz-crystal material is used as the piezoelectric vibrating piece 330. As illustrated in FIG. 14A, the piezoelectric vibrating piece 330 includes a vibrating portion 331, the framing portion 332, and an anchor portion 333. The vibrating portion 331 vibrates at a predetermined vibration frequency, and the framing portion 332 surrounds the vibrating portion 331, and the anchor portion 333 connects the vibrating portion 331 and the framing portion 332. Between the vibrating portion 331 and the framing portion 332, a through hole 334 is formed to penetrate the piezoelectric vibrating piece 330 in the Y axis direction except for the anchor portion 333.

The vibrating portion 331 has a rectangular shape, and the thickness of the vibrating portion 331 in the Y axis direction is the same as the thickness of the framing portion 332. The thickness of the vibrating portion 331 may be thinner than the thickness of the framing portion 332. Also, the vibrating portion 331 may have a mesa shape where the central portion is thicker than the peripheral portion. The framing portion 332 has a rectangular shape surrounding the vibrating portion 331, and the front surface 332a and back surface 332b of the framing portion 332 are respectively bonded to the bonding surface 310a of the lid 310 and the bonding surface 320a of the base 320.

On the front surface of the vibrating portion 331, an excitation electrode 335 is formed. From the excitation electrode 335, an extraction electrode 337 is formed to extend in the −X direction to the front surface of the anchor portion 333 and framing portion 332. Furthermore, the extraction electrode 337 is connected to an extraction electrode 337a formed on the back surface of the framing portion 332 via a through electrode 339 that penetrates the framing portion 332 in the Y direction. On the back surface of the vibrating portion 331, an excitation electrode 336 is formed. From the excitation electrode 336, an extraction electrode 338 is formed to extend in the −X direction to the back surface of the anchor portion 333 and framing portion 332.

As illustrated in FIG. 14B, the excitation electrodes 335 and 336, extraction electrodes 337 and 338, and similar electrodes have a two-layered structure including base layers 335a and 336a made of, for example, a nickel-tungsten for increasing adhesion with a quartz-crystal material, and main electrode layers 335b and 336b such as a gold. Metals used as the base layer 335a and similar layer, and the main electrode layer 335b and similar main electrode are similar to the metals used as those of the first and second embodiments.

As illustrated in FIG. 14B, on the excitation electrodes 335 and 336, cap layers 341a and 342a are formed so as to coat the respective excitation electrodes 335 and 336. The cap layers 341a and 342a have the approximately same size as the excitation electrodes 335 and 336. However, the cap layers 341a and 342a may be formed at a slightly larger region so as to cover including side surfaces of the excitation electrodes 335 and 336. Furthermore, the cap layers 341a and 342a may be formed on the extraction electrodes 337 and 338. In this case, among the extraction electrodes 337 and 338, the cap layers 341a and 342a may not be formed at regions to be connected to connecting electrodes 322 and 323 of a base 320. While the film thickness of the cap layers 341a and 342a is not specifically limited, the film thickness is set to from several nm to several 10 nm.

The cap layers 341a and 342a includes a conductive oxide or conductive nitride whose sputtering rate is lower than the sputtering rate of the metal used as the main electrode layers 335b and 336b of the excitation electrodes 335 and 336. Examples of the conductive oxide or conductive nitride used as the cap layers 341a and 342a include titanium oxide, titanium oxide to which aluminum is doped, titanium nitride, or a similar material, which are similar to the materials used as those of the first and second embodiments.

As illustrated in FIG. 13A and FIG. 13B, in the piezoelectric vibrating piece 330, the front surface 332a of the framing portion 332 of the piezoelectric vibrating piece 330 is directly bonded to the bonding surface 310a of the lid 310. Also, the back surface 332b of the framing portion 332 of the piezoelectric vibrating piece 330 is bonded to the bonding surface 320a of the base 320. The back surface 332b and the bonding surface 320a may be bonded directly or may be bonded using a bonding material. Bonding the piezoelectric vibrating piece 330 to the base 320 makes an electrical connection between the extraction electrodes 337a and 338, and the connecting electrodes 322 and 323. Note that the extraction electrodes 337a and 338 and the connecting electrodes 322 and 323 may be connected via conductive adhesives. Bonding the lid 310 and base 320 to the piezoelectric vibrating piece 330 makes a cavity 340 that houses the vibrating portion 331 of the piezoelectric vibrating piece 330. The inside of the cavity 340 is sealed under a vacuum atmosphere or an inert gas atmosphere such as a nitrogen gas.

Thus, according to the piezoelectric device 300a, the cap layers 341a and 342a are formed on the excitation electrodes 335 and 336. Accordingly, the excitation electrodes 335 and 336 are coated by the cap layers 341a and 342a which have a low sputtering rate by which the damage and similar failures of the excitation electrodes 335 and 336 can be prevented, and thus improving the reliability.

### Fabricating Method of Piezoelectric Device 300a

The method for fabricating the piezoelectric device 300a according to the fifth embodiment differs from the above-described each embodiment. They differ in a formation process of the coating layers (the cap layers) 341a and 342a in the following point. The cap layers 341a and 342a are formed on the excitation electrodes 335 and 336. The cap layers 341a and 342a are formed by, for example, sputtering or vacuum evaporation using a metal mask stencil, photolithography, and etching similar to the first embodiment. Then, a film of conductive oxide or conductive nitride with a lower sputtering rate than the sputtering rate of the excitation electrodes 335 and similar electrode is formed. Thus, the cap layers 341a and 342a are formed (a cap formation process). A process of doping tin after film formation of indium oxide, a process of doping antimony after film formation of tin oxide, a process of doping aluminum after film formation of titanium oxide, and a process of doping any one of indium, gallium, or aluminum after film formation of zinc oxide may be performed. This doping is performed by simply sputtering a target including a doping element. Regarding titanium oxide, instead of doping of aluminum, reduction treatment (H₂ annealing) may be performed.

On the other hand, similar to the respective above-described embodiments, the surfaces of the lid wafer LW2 and the piezoelectric wafer AW2 are sputter etched to be decontaminated by the argon beam IB. Note that similar to the fourth embodiment, an iron, a chrome, an aluminum and a similar metal are deposited on the piezoelectric wafer AW2 and similar wafer. Accordingly, the cap layers 341a and 342a become in a state where an iron, a chrome, an aluminum, or similar element are mixed to conductive oxide or conductive nitride, or in a state of a layered film of conductive oxide or conductive nitride and an iron, a chrome, an aluminum, or similar element. Note that, similar to the first embodiment, since the cap layers 341a and 342a have a sputtering rate lower than the sputtering rate of the excitation electrode 335 and similar electrode, the excitation electrodes 335 and 336 are not etched carelessly by the irradiation of the argon beam IB.

### Working Example

The following describes a working example. As the working example, a 40 MHz crystal resonator (piezoelectric device 100a) having a glass package structure illustrated in FIG. 10B was used. An AT-cut quartz-crystal vibrating piece was used as the piezoelectric vibrating piece. The excitation electrodes 131 and 132 were formed of: chrome layers (30 nm) as the base layers 131a and 132a; and silver layers (150 nm) as the main electrode layers 131b and 132b. The cap layers 141a and 142a were formed with titanium nitride (3 nm). As illustrated in FIG. 3A and FIG. 3B, the quartz-crystal vibrating piece was mounted on a 6-inch base wafer BW1 by a conductive paste, then the base wafer BW1 was bonded to a 6-inch lid wafer LW1 by the ion beam activation bonding apparatus 10 illustrated in FIG. 4 to fabricate the 40 MHz crystal resonator.

As a comparative example, a 40 MHz AT-cut crystal resonator includes excitation electrodes, without cap layers. The excitation electrodes formed of chrome layers (30 nm) (base layers) and silver layers (150 nm) (main electrode layers) were fabricated through the same fabrication process as the working example. Note that the electrode materials were formed by an electron-beam evaporation method.

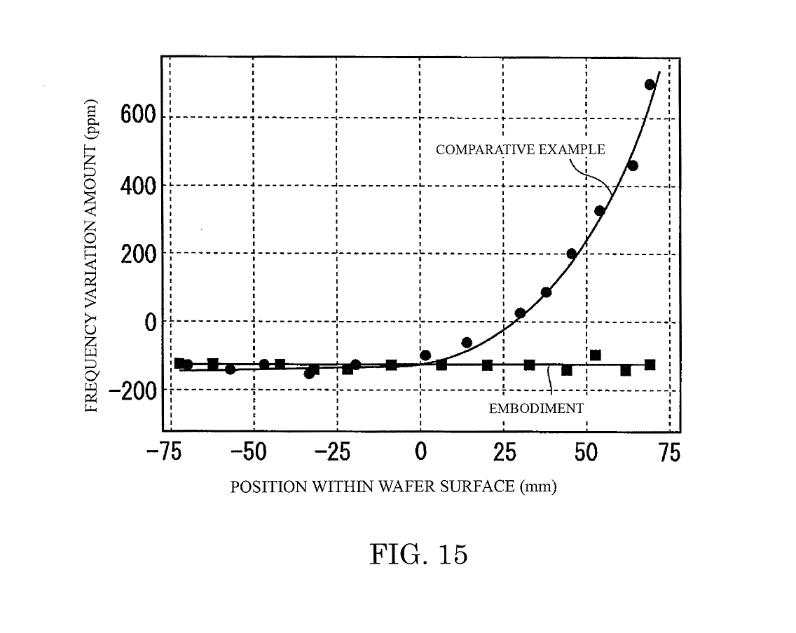

The frequency variation amounts between before and after the bonding of the base wafer BW1 and the lid wafer LW1 were measured, and then the distributions of the frequency variation amounts within the wafer surfaces were compared for the working example and the comparative example. Note that, in each case, frequency adjustment was performed when the quartz-crystal vibrating piece was mounted on the base wafer BW1, and then both frequencies within the surfaces were set to 40 MHz. FIG. 15 is a diagram plotting the fluctuation of the frequency variation amounts along the direction parallel to the central axis of the ion source 50 within the 6-inch wafer for the working example and the comparative example. In FIG. 15, the positive direction of the horizontal axis is the side of the ion source 50.

In the working example, the frequency variation is constant and is about −120 ppm at the positions within the wafer surface, while in the comparative example, the frequency variation amount is large and is +750 ppm at the positive side (the side close to the ion source 50) of the horizontal axis, and the frequency variation amount decreases as moving toward the center, then approaches −120 ppm as moving from the center of wafer toward the end in the direction opposite to the ion source 50. A silver is etched more at the side close to the ion source 50 since etching strength of an argon beam is stronger than the deposited metals. Since a silver has a high sputtering rate and a high density, the frequency variation is remarkable. As moving away from the ion source 50 (toward the negative side of the horizontal axis in FIG. 15), the contribution of etching to the frequency variation is gradually decreased, while the contribution of the deposited metals to the frequency variation appears.

In the working example, thanks to the cap layer 141a and similar layer made of titanium nitride, only frequency variation caused by the deposited metals is observed within not only, for example, the main electrode layer 131b made of a silver but also the entire 6-inch wafer since the etching effect to the cap layer 141a and similar layer is extremely small. In the working example, adjusting the frequency to a target frequency +120 ppm in the frequency adjustment process before the bonding of the lid wafer LW1 and the base wafer BW1 allows fabricating a 40 MHz-frequency crystal resonator after the bonding. While titanium nitride was used as the cap layer 141a and similar layer in the working example, the similar results were obtained by using indium oxide, tin oxide, ruthenium oxide, titanium oxide, indium oxide in which tin is doped, tin oxide in which antimony is doped, titanium oxide in which aluminum is doped, zinc oxide to which any one of indium, gallium, or aluminum is doped, hafnium nitride, tantalum nitride, tungsten nitride, and zirconium nitride.

This disclosure provides a piezoelectric device that includes a piezoelectric vibrating piece and a coating layer. The piezoelectric vibrating piece includes an electrode. The piezoelectric vibrating piece includes a cap layer that coats the electrode. The cap layer is formed of a conductive oxide or conductive nitride that has a sputtering rate lower than a sputtering rate of the electrode.

The piezoelectric device also may include a lid and a base bonded to one another. The piezoelectric vibrating piece may be disposed at a depressed portion formed at least one of the lid and the base. The lid and the base may be bonded to each other directly. The piezoelectric vibrating piece includes a vibrating portion, a framing portion, and an anchor portion. The framing portion surrounds the vibrating portion. The anchor portion connects the vibrating portion and the framing portion. The piezoelectric vibrating piece includes a lid and a base bonded to respective front surface and back surface of the framing portion. The framing portion and the lid are bonded to each other directly. The cap layer can apply a conductive oxide of any of an indium oxide (In₂O₃), a tin oxide (SnO₂), a ruthenium oxide (RuO₂), and a titanium oxide (TiO₂). The cap layer can apply a conductive oxide of any of an indium oxide (In₂O₃) in which a tin (Sn) is doped, a tin oxide (SnO₂) in which an antimony (Sb) is doped, a titanium oxide (TiO₂) in which an aluminum (Al) is doped, and a zinc oxide (ZnO) in which one of an indium (In), a gallium (Ga), and an aluminum (Al) is doped. The cap layer can apply a conductive nitride of any of a hafnium nitride (HfN), a titanium nitride (TiN), a tantalum nitride (TaN), a tungsten nitride (WN), and a zirconium nitride (ZrN).

This disclosure is a method for fabricating a piezoelectric device. The piezoelectric device includes a piezoelectric vibrating piece where an electrode is formed. The method includes forming a cap. The forming forms a cap layer with a conductive oxide or a conductive nitride having a lower sputtering rate than a sputtering rate of the electrode so as to coat the electrode of the piezoelectric vibrating piece.

The method for fabricating a piezoelectric device may include mounting and bonding a lid. The mounting mount the piezoelectric vibrating piece on a base. The bonding bonds a lid to the base using an ion-beam activation bonding. The method may include bonding a base and bonding a lid. The bonding a base bonds a base on a back surface of a framing portion. The method uses the piezoelectric vibrating piece that includes a vibrating portion, a framing portion, and an anchor portion. The framing portion surrounds the vibrating portion. The anchor portion connects the vibrating portion and the framing portion. The bonding a lid bonds a lid to a surface of the framing portion using an ion-beam activation bonding. The bonding a lid may be performed under vacuum atmosphere.

This disclosure can prevent the damage or similar failures of the electrodes to improve the reliability of the piezoelectric device by coating the electrodes formed on the piezoelectric vibrating piece with the cap layers. Furthermore, even if the ion-beam activation bonding method or any similar bonding method is used for bonding the lid, this disclosure prevents the electrode from being etched carelessly reduces the variation of the resonance frequency of the piezoelectric vibrating piece, and thus preventing the production of inferior products to improve the production yield.

### Configuration of Piezoelectric Device 100b According to Seventh Embodiment

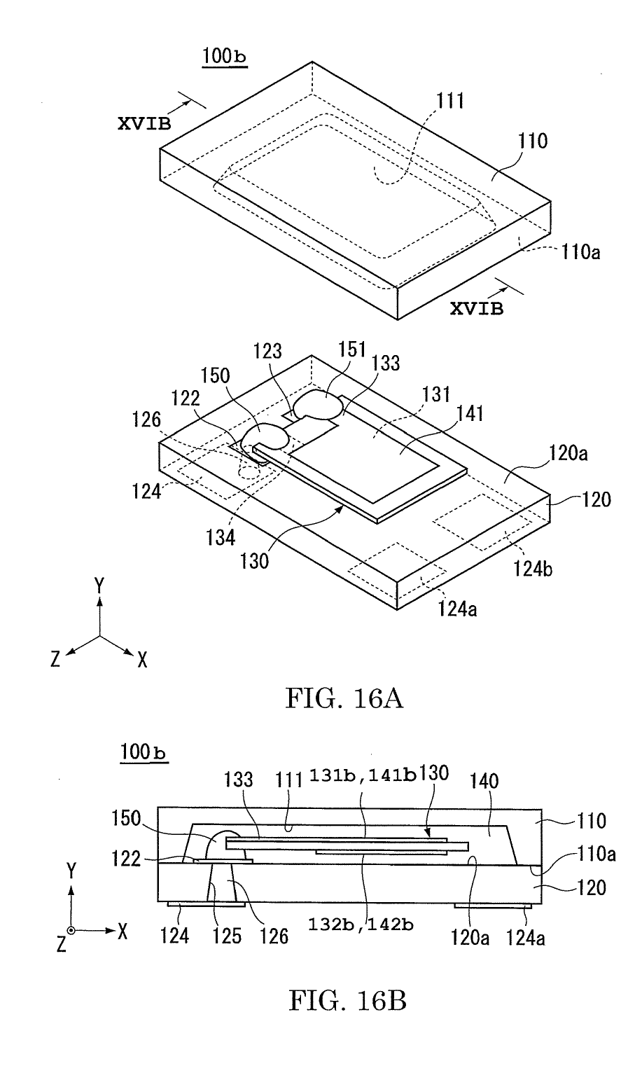

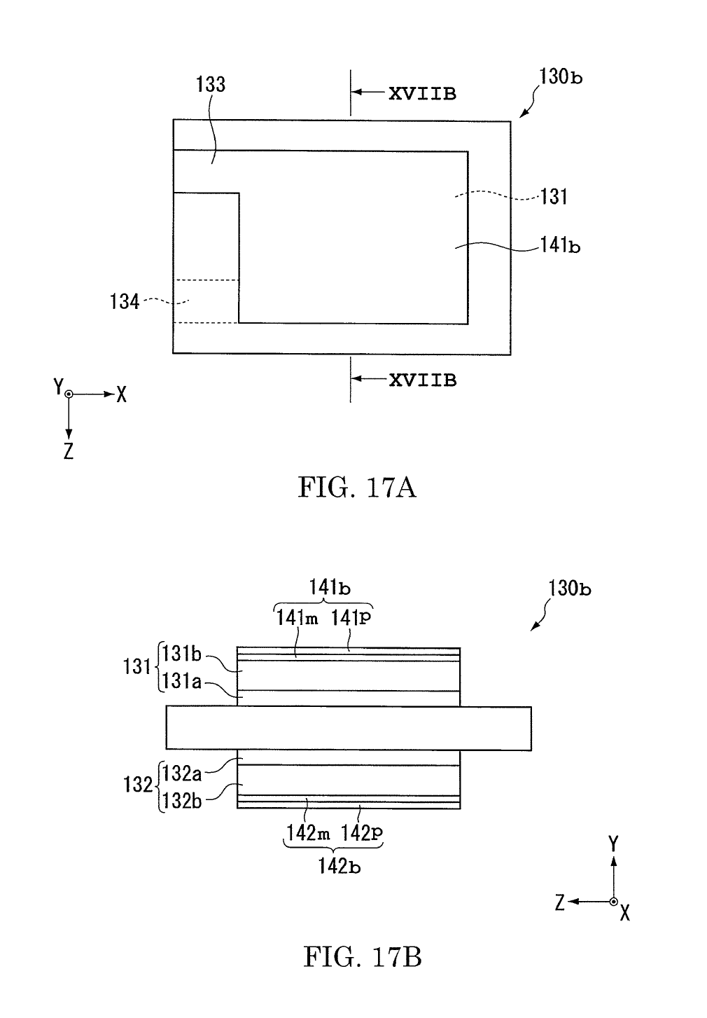

The following describes the seventh embodiment. In the following description, like reference numerals designate identical or corresponding parts of the first embodiment, and therefore such elements will not be further elaborated here. FIG. 16A, FIG. 16B, FIG. 17A, and FIG. 17B illustrate a piezoelectric device 100b according to the seventh embodiment. In addition, FIG. 16B illustrates a cross-sectional view taken along the line corresponding to the line XVIB-XVIB of FIG. 16A. The piezoelectric device 100b includes a piezoelectric vibrating piece 130b. The seventh embodiment differs from each above-described embodiment in a configuration of a coating layer (a cap layer).

On the excitation electrodes 131 and 132, as illustrated in FIG. 17B, cap layers 141b and 142b are formed. The cap layers 141b and 142b serve as a coating layer that coats the respective excitation electrodes 131 and 132. The cap layers 141b and 142b have the approximately same size as the excitation electrodes 131 and 132. However, the cap layers 141b and 142b may be formed at a slightly larger region so as to cover including side surfaces of the excitation electrodes 131 and 132. Furthermore, the cap layers 141b and 142b may be formed on the extraction electrodes 133 and 134. In this case, among the extraction electrodes 133 and 134, the cap layers 141b and 142b are not formed at regions where the conductive adhesives 150 and 151, which will be described later, are applied. While the film thickness of the cap layers 141b and 142b is not specifically limited, the film thickness is set to from several nm to several 10 nm.

The cap layers 141b and 142b include, as illustrated in FIG. 17B, metal layers 141m and 142m and protective films 141p and 142p. The protective films 141p and 142p are formed on the metal layers 141m and 142m. The metal layers 141m and 142m include metals with a lower sputtering rate than metals used for the main electrode layers 131b and 132b of the excitation electrodes 131 and 132. Metals used as the metal layers 141m and 142m are, for example, an aluminum (Al), a titanium (Ti), a vanadium (V), a zirconium (Zr), a niobium (Nb), a molybdenum (Mo), a hafnium (Hf), a tantalum (Ta), and a tungsten (W).

The following is the sputter etching effects by the irradiation of argon ion beam (argon beam). When an ion beam is vertically irradiated, assuming that the sputtering rate of silver is normalized to 1, a sputtering rate of gold is 0.71. Then, a sputtering rate is as follows: aluminum is 0.36, titanium is 0.17, vanadium is 0.21, zirconium is 0.22, niobium is 0.19, molybdenum is 0.19, hafnium is 0.24, tantalum is 0.18, and tungsten is 0.18. All the metal has a lower sputtering rate than the sputtering rate of gold and silver of the main electrode layers 131b and 132b. Note that the amount of frequency variation due to the sputtering of the excitation electrodes 131 and 132 is proportional to the etched mass of the excitation electrodes 131 and 132 by sputtering. Accordingly, since the density of, for example, a metal such as an aluminum and titanium is low, and therefore the multiplication of the sputtering rate and density of the aluminum and titanium is a low value so that using the aluminum and titanium as the metal layers 141m and 142m advantageously allows the amount of frequency variation to decrease.

The protective films 141p and 142p are metal oxide films used for the metal layers 141m and 142m, films of mixing the metal oxide and other metals, or laminated films of the metal oxide and another metal. Other metals are, for example, an iron (Fe), a chrome (Cr), and an aluminum (Al). The other metals are used for an ion source main body of the ion beam activation bonding apparatus 10, which will be described later, and a constituent material of a bonding chamber. An oxide film or a similar film has a lower sputtering rate than that of metals (a gold or a silver) used for the main electrode layers 131b and 132b, and also has a lower sputtering rate than that of the metals used for the cap layers 141b and 142b. The film of the oxide is a natural oxide film formed by, for example, oxidizing metals in the metal layers 141m and 142m by oxygen in the atmosphere.

As illustrated in FIG. 16A and FIG. 16B, the piezoelectric vibrating piece 130b is supported on the front surface 120a of the base 120 by the conductive adhesives 150 and 151. The extraction electrode 134 and connecting electrode 122 are electrically connected via the conductive adhesive 150, while the extraction electrode 133 and the connecting electrode 123 are electrically connected via the conductive adhesive 151. Then, the lid 110 and the base 120 are bonded to each other. Accordingly, the piezoelectric vibrating piece 130b is housed in the cavity 140. The inside of the cavity 140 is sealed under a vacuum atmosphere or an inert gas atmosphere of for example, a nitrogen gas. Note that the bonding surface 110a of the lid 110 and the front surface 120a of the base 120 are directly bonded to each other without, for example, a bonding material.

Thus, according to the piezoelectric device 100b, since the cap layers 141b and 142b are formed on the excitation electrodes 131 and 132, the excitation electrodes 131 and 132 are coated by the cap layers 141b and 142b which have a low sputtering rate by which the damage and similar failures of the excitation electrodes 131 and 132 can be prevented and thus improving the reliability.

### Fabricating Method of Piezoelectric Device 100b

The method for fabricating the piezoelectric device 100b according to the seventh embodiment differs from the each above-described embodiment. They differ in a formation process of the coating layers (the cap layers) 141b and 142b in the following point. The cap layers 141b and 142b are formed on the excitation electrodes 131 and 132. The cap layers 141b and 142b are formed as follows. First, the metal layers 141m and 142m made of, for example, an aluminum or similar are formed by, for example, sputtering or vacuum evaporation using a metal mask stencil, photolithography, and etching (a cap formation process). Then, the film formation surfaces of the metal layers 141m and 142m are exposed to the atmosphere, thus natural oxide films are formed. The natural oxide films become the protective films 141p and 142p and (a protective film formation process). The protective film 141p or similar film is not limited to be formed by being exposed to the atmosphere; however, the protective film 141p or a similar film may be formed by evaporation or a similar method. After the cap layers 141b and 142b are formed, the piezoelectric wafer AW1 is diced along the scribe line. Accordingly, the individual piezoelectric vibrating pieces 130b are completed.

On the other hand, similar to the respective above-described embodiments, the surfaces of the lid wafer LW1 and base wafer BW1 are sputter etched to be removed contamination by the argon beam IB. At this time, having been exposed to the argon plasma, the members of the ion source 50, such as an anode, are sputtered. Accordingly, the argon beam IB irradiated from the ion source 50 includes an iron and a chrome, which are components of a stainless steel of which the ion source 50 is made. In addition, since the argon beam IB irradiated from the ion source 50 has a large divergence angle, the argon beam IB sputters not only the lid wafer LW1 and a similar wafer but also the stainless steel of the inner wall in the vacuum chamber 20 and other components that are made of aluminum alloy. This makes an iron, a chrome, an aluminum and similar elements deposited on the lid wafer LW1 and similar wafer. Namely, etching and deposition are carried out simultaneously on the surfaces of the lid wafer LW1 and the base wafer BW1. Accordingly, the protective films 141p and 142p become in a form of films where this oxide, an iron, a chrome, an aluminum, or similar element are mixed in addition to the metal oxide films used for the metal layers 141m and 142m, or in a form of a layered film of the oxide and an iron, a chrome, an aluminum, and similar elements.

As described above, the cap layers 141b and 142b (the protective films 141p and 142p) formed on the excitation electrodes 131 and 132 of the piezoelectric vibrating piece 130b have a sputtering rate lower than that of a gold or a silver used as the excitation electrode 131 and similar electrode. Accordingly, the excitation electrodes 131 and 132 are not etched carelessly by the irradiation of the argon beam IB since they are coated by the cap layers 141b and 142b (the protective films 141p and 142p).

On the other hand, the cap layer 141b or similar layer (the protective film 141p or similar film) have a low sputtering rate, as well as the argon beam IB is irradiated to the cap layer 141b or similar layer from the direction inclined by approximately 90 degree with respect to the vertical direction of the lid wafer LW and similar wafer as illustrated in FIG. 4. Accordingly, the actual sputtering rate is significantly low. Consequently, the cap layers 141b and 142b (the protective films 141p and 142p) are hardly etched, and only metal elements such as an iron, a chrome, or an aluminum are deposited on the cap layer 141b and similar layer.

Since the deposit amounts of the metals can be constant without being distributed within the wafer surfaces by decreasing the film thickness to several nm and optimizing the irradiation condition, the resonance frequencies of the piezoelectric devices 100b after bonding of the wafers uniformly shift toward the negative side within the wafer surface. In the frequency adjustment process to be done before the bonding process, adjusting the resonance frequencies with considering this shifting amount allows producing, with high production yield, the piezoelectric devices 100b having the desired resonance frequency after the bonding of the wafers by wafer level packaging using glass.

Thus, the fabrication method of the piezoelectric device 100b allows preventing the excitation electrode 131 and similar electrode of the piezoelectric vibrating piece 130b from being etched carelessly, and reduces the variation of the resonance frequency of the piezoelectric vibrating piece 130b to prevent the production of inferior products. Furthermore, if the protective film 141p or similar film of the cap layer 141b or similar layer is a natural oxide film, since they are formed by only being exposed to the atmosphere during a fabrication process, thus additional special treatment is unnecessary.

### Eighth Embodiment

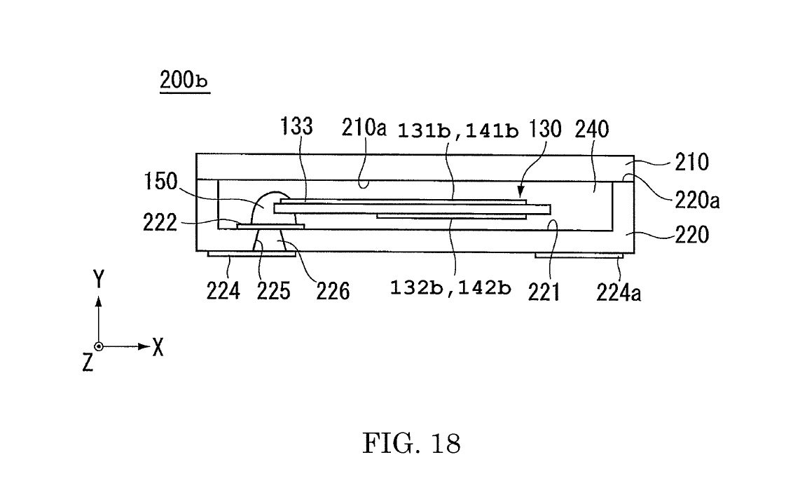

The following describes the eighth embodiment. In the following description, like reference numerals designate identical or corresponding parts of the seventh embodiment, and therefore such elements will not be further elaborated here. FIG. 18 illustrates a piezoelectric device 200b according to the eighth embodiment. In addition, FIG. 18 illustrates a cross-sectional view taken along the line corresponding to the line XVIB-XVIB of FIG. 16A. Similar to the seventh embodiment, the piezoelectric device 200b uses a piezoelectric vibrating piece 130b.

The piezoelectric device 200b includes a lid 210 and a base 220. As illustrated in FIG. 18, the lid 210 is a plate-shaped member having a rectangular shape in plan view. The back surface 210a (−Y-side surface) of the lid 210 has a bonding portion bonded to the base 220. The bonding portion has a sufficient flatness appropriate for bonding by the ion-beam activation bonding method (typically, average roughness Ra is around 1 nm).

The base 220 is a plate-shaped member having a rectangular shape in plan view, and has a depressed portion 221 at the central portion of the front surface side (+Y-side surface) as illustrated in FIG. 18. The depressed portion 221 is surrounded by a bonding surface 220a, which is bonded to the lid 210. Bonding the lid 210 and the base 220 forms a cavity 240 (housing space), which houses the piezoelectric vibrating piece 130b. Note that the bonding surface 220a has a sufficient flatness appropriate for bonding by the ion-beam activation bonding method (typically, average roughness Ra is around 1 nm).

A connecting electrode 222 is formed in the depressed portion 221 of the base 220, and an external electrode 224 is formed on the back surface of the base 220. A through hole 225 that penetrates the base 220 in the Y direction is formed. The through hole 225 includes a through electrode 226 that electrically connects the connecting electrode 222 and the external electrode 224. In addition, a dummy electrode 224a is formed on the back surface of the base 220. Note that the connecting electrode 222, the external electrode 224, and the through electrode 226 are approximately similar to those of the piezoelectric device 100b of the seventh embodiment.

Thus, according to the piezoelectric device 200b, since the piezoelectric vibrating piece 130b similar to that of the first embodiment is used, the excitation electrodes 131 and 132 are coated by the cap layers 141b and 142b so as to prevent the damage and similar failures of the excitation electrodes 131 and 132, thus improving the reliability. In addition, the fabrication method of the piezoelectric device 200b is approximately similar to the fabrication method of the piezoelectric device 100b except for that the depressed portion is not formed on the lid 210, and the depressed portion 221 is formed on the base 220. Accordingly, the fabrication method of the piezoelectric device 200 allows preventing the excitation electrode 131 and similar electrode from being etched carelessly, and reducing the variation of the resonance frequency of the piezoelectric vibrating piece 130b to prevent the production of inferior products.

### Configuration of Piezoelectric Device 300b According to Ninth Embodiment

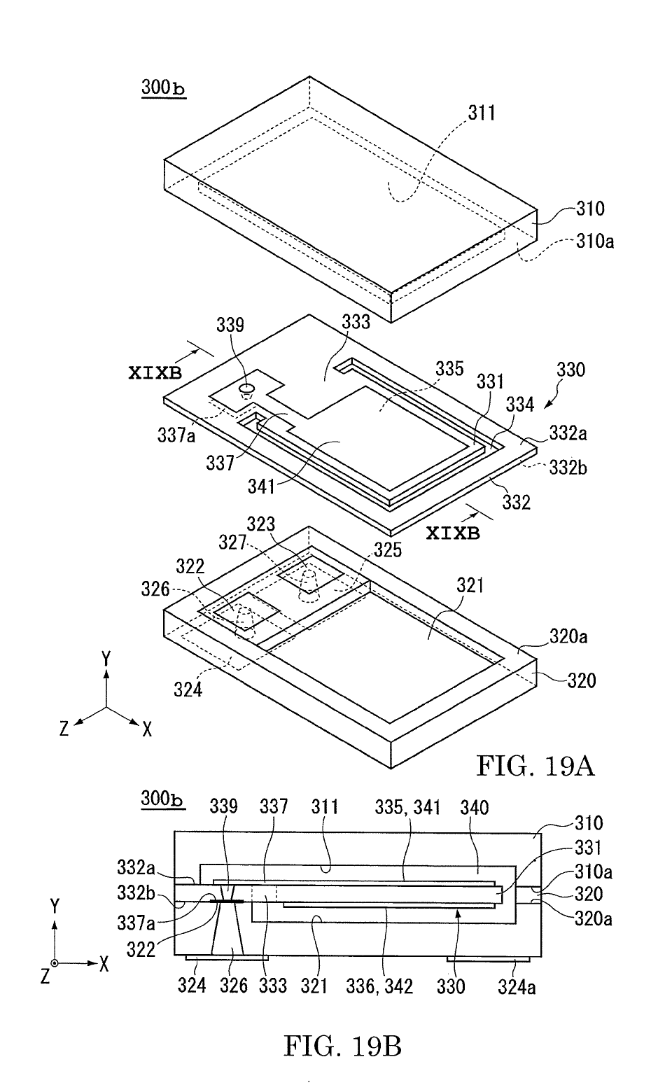

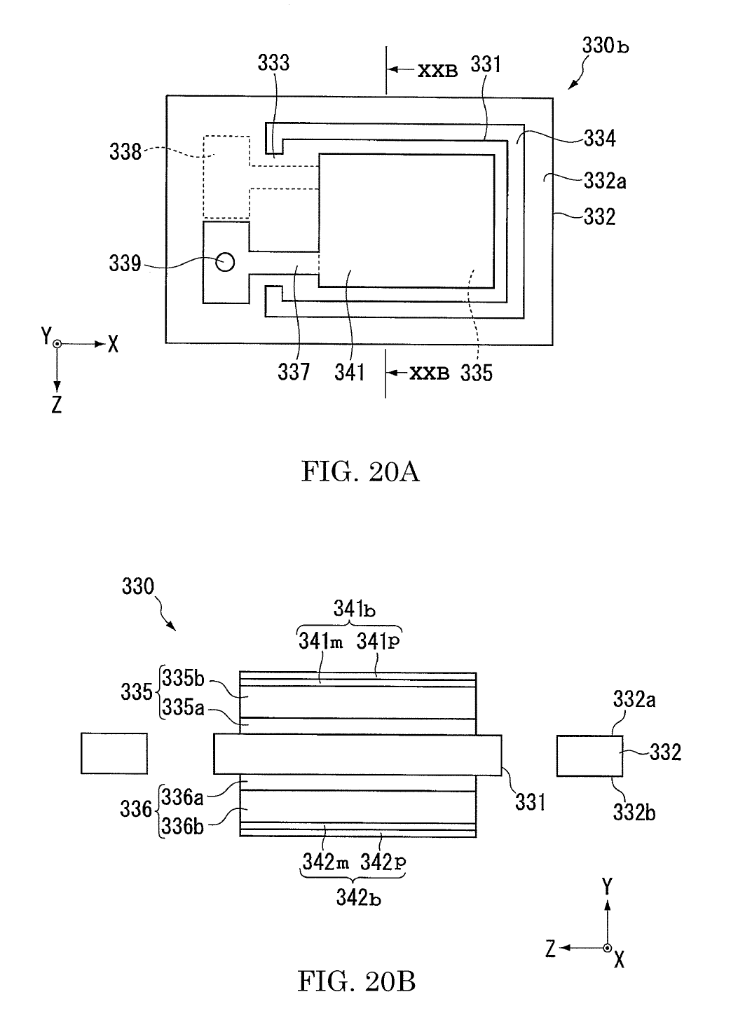

The following describes a piezoelectric device 300b according to the ninth embodiment with reference to FIG. 19A, FIG. 19B, FIG. 20A, and FIG. 20B. As illustrated in FIG. 19A, the piezoelectric device 300b includes a lid 310 and a base 320, which sandwich a piezoelectric vibrating piece 330. The lid 310 is bonded to the +Y-side of the piezoelectric vibrating piece 330, while the base 320 is bonded to the −Y-side of the piezoelectric vibrating piece 330. Similar to the seventh and eighth embodiments, the lid 310 and the base 320 are made of, for example, a borosilicate glass.

As illustrated in FIGS. 19A and 19B, the lid 310 is formed in a rectangular plate shape, and has a depressed portion 311 and a bonding surface 310a on the back surface (−Y-side surface). The bonding surface 310a surrounds the depressed portion 311. The bonding surface 310a is bonded to a front surface 332a (+Y-side surface) of a framing portion 332 of the piezoelectric vibrating piece 330 described below. The bonding surface 310a is directly bonded to the front surface 332a. Note that the bonding surface 310a and front surface 332a have a sufficient flatness appropriate for bonding by the ion-beam activation bonding method (typically, average roughness Ra is around 1 nm).

The base 320 is also formed of a rectangular plate shape and has a depressed portion 321 and a bonding surface 320a on the front surface (+Y-side surface). The bonding surface 320a surrounds the depressed portion 321. The bonding surface 320a faces a back surface 332b (−Y-side surface) of the framing portion 332 of the piezoelectric vibrating piece 330. As illustrated in FIG. 19B, the base 320 is bonded to the back surface (−Y-side surface side) side of the piezoelectric vibrating piece 330b by a bonding material (not illustrated) disposed between the bonding surface 320a and the back surface 332b of the framing portion 332. Besides the bonding surface 320a and the back surface 332b are bonded to each other directly, and the bonding surface 320a and the back surface 332b may be bonded using a bonding material such as a low melting point glass or a polyimide.

As illustrated in FIG. 19A and FIG. 19B, at the −X-side region of the front surface of the base 320, connecting electrodes 322 and 323 are formed, while at the −X-side region of the back surface of the base 320, external electrodes 324 and 325 are formed. In addition, the base 320 includes through electrodes 326 and 327 that penetrate the base 320 in the Y direction. The through electrode 326 electrically connects the connecting electrode 322 and the external electrode 324, while the through electrode 327 electrically connects the connecting electrode 323 and the external electrode 325. Note that, as illustrated in FIG. 19B, at the +X-side region of the back surface of the base 320, dummy electrodes 324a are formed.

The connecting electrodes 322 or similar electrode, the external electrodes 324 or a similar electrode, and the through electrodes 326 or a similar electrode are made of a metal similar to the metal used for those of the first and second embodiments. In addition, connecting means between: the connecting electrodes 322 and 323; and the external electrodes 324 and 325 is not limited to the through electrodes 326 and 327. For example, at the corners or the sides of the base 320, cutouts (castellations) may be formed, and then the connecting electrodes 322 and 323 and the external electrodes 324 and 325 may be connected to each other by electrodes formed at the cutouts.

Similar to the seventh and eighth embodiments, for example, an AT-cut quartz-crystal material is used as the piezoelectric vibrating piece 330. As illustrated in FIG. 20A, the piezoelectric vibrating piece 330 includes a vibrating portion 331, the framing portion 332, and an anchor portion 333. The vibrating portion 331 vibrates at a predetermined vibration frequency, and the framing portion 332 surrounds the vibrating portion 331, and the anchor portion 333 connects the vibrating portion 331 and the framing portion 332. Between the vibrating portion 331 and the framing portion 332, a through hole 334 is formed to penetrate the piezoelectric vibrating piece 330 in the Y axis direction except for the anchor portion 333.

The vibrating portion 331 has a rectangular shape, and the thickness of the vibrating portion 331 in the Y-axis direction is the same as that of the framing portion 332. The thickness of the vibrating portion 331 may be thinner than the thickness of the framing portion 332. Also, the vibrating portion 331 may have a mesa shape where the central portion is thicker than the peripheral portion. The framing portion 332 has a rectangular shape surrounding the vibrating portion 331, and the front surface 332a and back surface 332b of the framing portion 332 are respectively bonded to the bonding surface 310a of the lid 310 and the bonding surface 320a of the base 320.

On the front surface of the vibrating portion 331, an excitation electrode 335 is formed. From the excitation electrode 335, an extraction electrode 337 is formed to extend in the −X direction to the front surface of the anchor portion 333 and framing portion 332. Furthermore, the extraction electrode 337 is connected to an extraction electrode 337a formed on the back surface of the framing portion 332 via a through electrode 339 that penetrates the framing portion 332 in the Y direction. On the back surface of the vibrating portion 331, an excitation electrode 336 is formed. From the excitation electrode 336, an extraction electrode 338 is formed to extend in the −X direction to the back surface of the anchor portion 333 and framing portion 332.

As illustrated in FIG. 20B, the excitation electrodes 335 and 336, extraction electrodes 337 and 338, and similar electrodes have a two-layered structure including base layers 335a and 336a made of, for example, a nickel-tungsten for increasing adhesion with a quartz-crystal material and main electrode layers 335b and 336b such as a gold. Metals used as the base layer 335a and similar layer, and the main electrode layer 335b and similar main electrode are similar to the metals used as those of the first and second embodiments.

As illustrated in FIG. 20B, on the excitation electrodes 335 and 336, cap layers 341b and 342b are formed so as to coat the respective excitation electrodes 335 and 336. The cap layers 341b and 342b have the approximately same size as the excitation electrodes 335 and 336. However, the cap layers 341b and 342b may be formed at a slightly larger region so as to cover including side surfaces of the excitation electrodes 335 and 336. Furthermore, the cap layers 341b and 342b may be formed on the extraction electrodes 337 and 338. In this case, among the extraction electrodes 337 and 338, the cap layers 341b and 342b are not formed at regions to be connected to connecting electrodes 322 and 323 of a base 320. While the film thickness of the cap layers 341b and 342b is not specifically limited, the film thickness is set to from several nm to several 10 nm.

The cap layers 341b and 342b include, as illustrated in FIG. 20B, metal layers 341m and 342m and protective films 341p and 342p. The protective films 341p and 342p are formed on the metal layers 341m and 342m. The metal layers 341m and 342m includes metals with a lower sputtering rate than the sputtering rate of metals used for the main electrode layers 335b and 336b of the excitation electrodes 335 and 336. Metals used as the metal layers 341m and 342m are similar to the materials used as those of the first and second embodiments, for example, an aluminum.

The protective films 341p and 342p are metal oxide films used for the metal layers 341m and 342m, films of mixing the metal oxide and other metals, or laminated films of the metal oxide and other metals. The protective films 341p and 342p are similar to those of the first and second embodiment; therefore, the explanations will not be further elaborated here.

As illustrated in FIG. 19A and FIG. 19B, in the piezoelectric vibrating piece 330, the front surface 332a of the framing portion 332 of the piezoelectric vibrating piece 330 is directly bonded to the bonding surface 310a of the lid 310. Also, the back surface 332b of the framing portion 332 of the piezoelectric vibrating piece 330 is bonded to the bonding surface 320a of the base 320. The back surface 332b and the bonding surface 320a may be bonded directly or may be bonded using a bonding material. Bonding the piezoelectric vibrating piece 330 to the base 320 makes an electrical connection between the extraction electrodes 337a and 338, and the connecting electrodes 322 and 323. Note that the extraction electrodes 337a and 338, and the connecting electrodes 322 and 323 may be connected via conductive adhesives. Bonding the lid 310 and base 320 to the piezoelectric vibrating piece 330 makes a cavity 340 that houses the vibrating portion 331 of the piezoelectric vibrating piece 330. The inside of the cavity 340 is sealed under a vacuum atmosphere or an inert gas atmosphere such as a nitrogen gas.

Thus, according to the piezoelectric device 300b, the cap layers 341b and 342b are formed on the excitation electrodes 335 and 336. Accordingly, the excitation electrodes 335 and 336 are coated by the cap layers 341b and 342b which have a low sputtering rate by which the damage and similar failures of the excitation electrodes 335 and 336 can be prevented and thus improving the reliability.

### Fabricating Method of Piezoelectric Device 300b

The method for fabricating the piezoelectric device 300b according to the eighth embodiment differs from each above-described embodiment. They differ in a formation process of the coating layers (the cap layers) 341a and 342a in the following point. The cap layers 341b and 342b are formed on the excitation electrodes 335 and 336. Similar to the first embodiment, the cap layers 341b and 342b are formed as follows. First, the metal layers 341m and 342m made of, for example, an aluminum are formed (a cap formation process). Then, the film formation surfaces of the metal layers 341m and 342m are exposed to the atmosphere, and thus natural oxide films are formed. The natural oxide films become the protective films 341p and 342p (a protective film formation process). The protective film 341p and similar film are not limited to be formed by being exposed to the atmosphere; however, the protective film 341p and similar film may be formed by evaporation or a similar method.

On the other hand, similar to the respective above-described embodiments, the surfaces of the lid wafer LW2 and the piezoelectric wafer AW2 are sputter etched to be decontaminated by the argon beam IB. Similar to the seventh embodiment, on the piezoelectric wafer AW2 or similar wafer, an iron, a chrome, and aluminum, or similar element is deposited. Accordingly, the protective films 341p and 342p become in a form of films where this oxide, an iron, a chrome, an aluminum, or similar element are mixed in addition to the metal oxide films used for the metal layers 341m and 342m, or in a form of a layered film of the oxide and an iron, a chrome, an aluminum, and similar elements. Note that, similar to the seventh embodiment, since the cap layers 341b and 342b (the protective films 341p and 342p) have a sputtering rate lower than the sputtering rate of the excitation electrode 335 and similar electrode, the excitation electrodes 335 and 336 are not etched carelessly by the irradiation of the argon beam IB.

### Working Example

The following describes a working example. As the working example, a 26 MHz crystal resonator (piezoelectric device 100b) having a glass package structure illustrated in FIG. 16B was used. An AT-cut quartz-crystal vibrating piece was used as the piezoelectric vibrating piece. The excitation electrodes 131 and 132 were formed of: chrome layers (30 nm) as the base layers 131a and 132a; and silver layers (150 nm) as the main electrode layers 131b and 132b. The cap layers 141b and 142b were formed at an aluminum (3 nm) as the metal layers 141m and 142m. As illustrated in FIG. 3A and FIG. 3B, the quartz-crystal vibrating piece was mounted on a 6-inch base wafer BW1 by a conductive paste, and then the base wafer BW1 was bonded to a 6-inch lid wafer LW1 by the ion beam activation bonding apparatus 10 illustrated in FIG. 4 to fabricate the 26 MHz crystal resonator. The protective film 141p or similar film of the cap layers 141b and 142b is formed as an oxidized film by being exposed in the atmosphere after film formation of an aluminum.

As a comparative example, a 26 MHz AT-cut crystal resonator having excitation electrodes without the cap layers was used. The excitation electrodes formed of chrome layers (30 nm) (base layer) and silver layers (150 nm) (main electrode layer) were fabricated through the same fabrication process as the working example. Note that the electrode materials were formed by an electron-beam evaporation method.

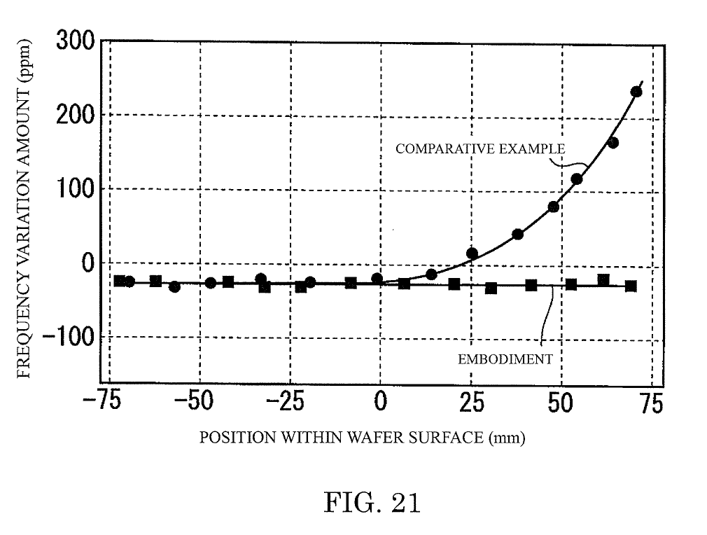

The frequency variation amounts between before and after the bonding of the base wafer BW1 and the lid wafer LW1 were measured, and then the distributions of the frequency variation amounts within the wafer surfaces were compared for the working example and the comparative example. Note that, in each case, frequency adjustment was performed when the quartz-crystal vibrating piece was mounted on the base wafer BW1, and then both frequencies within the surfaces were set to 26 MHz. FIG. 21 is a diagram plotting the fluctuation of the frequency variation amounts along the direction parallel to the central axis of the ion source 50 within the 6-inch wafer for the working example and the comparative example. In FIG. 21, the positive direction of the horizontal axis is the side of the ion source 50.

In the working example, the frequency variation is constant and is about −30 ppm at the positions within the wafer surface, while in the comparative example, the frequency variation amount is large and is +250 ppm at the positive side (the side close to the ion source 50) of the horizontal axis, and the frequency variation amount decreases as moving toward the center and then approaches −30 ppm as moving from the center of wafer toward the end in the direction opposite to the ion source 50. A silver is etched more at the side close to the ion source 50 since etching strength of an argon beam is stronger than the deposited metals. Since a silver has a high sputtering rate and a high density, the frequency variation is remarkable. As moving away from the ion source 50 (toward the negative side of the horizontal axis in FIG. 21), the contribution of etching to the frequency variation is gradually decreased, while the contribution of the deposited metals to the frequency variation appears.

In the working example, thanks to the cap layer 141b and similar layer made of an aluminum, only frequency variation caused by the deposited metals is observed within not only, for example, the main electrode layer 131b made of a silver but also the entire 6-inch wafer since the etching effect to the cap layer 141b and similar layer is extremely small. In the working example, adjusting the frequency to a target frequency +30 ppm in the frequency adjustment process before the bonding of the lid wafer LW1 and the base wafer BW1 allows fabricating a 26 MHz-frequency crystal resonator after the bonding. While an aluminum was used as the cap layer 141b and similar layer in the working example, the similar results were obtained by using a titanium, a vanadium, a zirconium, a niobium, a molybdenum, a hafnium, a tantalum, and a tungsten.

This disclosure is a piezoelectric device that includes a piezoelectric vibrating piece. The piezoelectric vibrating piece includes an electrode. The piezoelectric vibrating piece includes a cap layer that coats the electrode. The cap layer includes a metal with a lower sputtering rate than a sputtering rate of the electrode. A protective film is formed on a surface of the metal. The protective film is any one of a film of an oxide of the metal, a film where the metal oxide and another metal are mixed, and a laminated film of the metal oxide and another metal.

The piezoelectric device also may include a lid and a base bonded to one another. The piezoelectric vibrating piece may be disposed at a depressed portion formed at least one of the lid and the base. The lid and the base may be bonded to each other directly. The piezoelectric vibrating piece may include a vibrating portion, a framing portion, and an anchor portion. The framing portion surrounds the vibrating portion. The anchor portion connects the vibrating portion and the framing portion. The piezoelectric vibrating piece includes the lid and the base bonded to respective front surface and back surface of the framing portion. The framing portion and the lid are bonded to each other directly. A metal used for the cap layer can apply any of an aluminum (Al), a titanium (Ti), a vanadium (V), a zirconium (Zr), a niobium (Nb), a molybdenum (Mo), a hafnium (Hf), a tantalum (Ta), and a tungsten (W).

This disclosure provides a method for fabricating a piezoelectric device that includes a piezoelectric vibrating piece where an electrode is formed. The method includes forming a cap and a forming a protective film. The forming a cap forms a cap layer with a metal having a lower sputtering rate than a sputtering rate of the electrode so as to coat the electrode of the piezoelectric vibrating piece. The forming a protective film forms a protective film on a surface of the cap layer. The protective film is any one of a film of an oxide of the metal, a film where the metal oxide and another metal are mixed, and a laminated film of the metal oxide and another metal.

The method for fabricating a piezoelectric device may include mounting the piezoelectric vibrating piece on a base and bonding a lid to the base using an ion-beam activation bonding. The bonding may include the piezoelectric vibrating piece that includes a vibrating portion, a framing portion, and an anchor portion. The framing portion surrounds the vibrating portion. The anchor portion connects the vibrating portion and the framing portion. The method for fabricating a piezoelectric device may include bonding a base and bonding a lid. The bonding a base bonds the base on a back surface of the framing portion. The bonding a lid bonds the lid to a surface of the framing portion using an ion-beam activation bonding. The bonding a lid may be performed under vacuum atmosphere.

This disclosure can prevent the damage or similar failures of the electrodes to improve the reliability of the piezoelectric device by coating the electrodes formed on the piezoelectric vibrating piece with the cap layers. Furthermore, even if the ion-beam activation bonding method or any similar bonding method is used for bonding the lid, this disclosure prevents the electrode from being etched carelessly, reduces the variation of the resonance frequency of the piezoelectric vibrating piece, and thus preventing the production of inferior products to improve the production yield.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents used, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece that includes an electrode and an exposed portion; and
a coating layer constituted of a material with a sputtering rate lower than a sputtering rate of a material of the electrode, the coating layer covering the exposed portion.

2. The piezoelectric device according to claim 1, wherein
the material of the coating layer is an insulator or a dielectric.

3. The piezoelectric device according to claim 2, further comprising
a lid and a base bonded to one another, wherein
the piezoelectric vibrating piece is disposed at a depressed portion formed at least one of the lid and the base, and
the lid and the base are bonded to each other directly.

4. The piezoelectric device according to claim 2, wherein
the piezoelectric vibrating piece includes a vibrating portion, a framing portion, and an anchor portion, the framing portion surrounding the vibrating portion, the anchor portion connecting the vibrating portion and the framing portion,
the piezoelectric vibrating piece includes a lid and a base, the lid and the base being bonded to respective front surface and back surface of the framing portion, and
the framing portion and the lid are bonded to each other directly.

5. The piezoelectric device according to claim 2, wherein
the base includes an exposed portion and a coating layer of an insulator or a dielectric on the exposed portion of the base.

6. The piezoelectric device according to claim 2, wherein
the coating layer is an oxide based insulator or dielectric selected from the group consisting of an aluminum oxide (Al₂O₃), a silicon oxide (SiO₂), a magnesium oxide (MgO), a titanium oxide (TiO₂), and a zirconium oxide (ZrO₂).

7. The piezoelectric device according to claim 2, wherein
the coating layer is a nitride based insulator or dielectric selected from the group consisting of a boron nitride (BN), an aluminum nitride (AlN), and a silicon nitride (SiN).

8. The piezoelectric device according to claim 1, wherein
the coating layer is a cap layer that coats the electrode, and
the cap layer employs a conductive oxide or conductive nitride with a lower sputtering rate than a sputtering rate of a material of the electrode.

9. The piezoelectric device according to claim 8, wherein
the cap layer employs the conductive oxide selected from the group consisting of an indium oxide (In₂O₃), a tin oxide (SnO₂), a ruthenium oxide (RuO₂), and a titanium oxide (TiO₂).

10. The piezoelectric device according to claim 8, wherein
the cap layer employs the conductive oxide selected from the group consisting of an indium oxide (In₂O₃) to which a tin (Sn) is doped, a tin oxide (SnO₂) to which an antimony (Sb) is doped, a titanium oxide (TiO₂) to which an aluminum (Al) is doped, and a zinc oxide (ZnO) to which one of an indium (In), a gallium (Ga), and an aluminum (Al) is doped.

11. The piezoelectric device according to claim 8, wherein
the cap layer employs the conductive nitride selected from the group consisting of a hafnium nitride (HfN), a titanium nitride (TiN), a tantalum nitride (TaN), a tungsten nitride (WN), and a zirconium nitride (ZrN).

12. The piezoelectric device according to claim 1, wherein
the coating layer is a cap layer that coats the electrode,
the cap layer employs a metal with a lower sputtering rate than a sputtering rate of a material of the electrode, a protective film being formed on a surface of the metal, and
the protective film is a film selected from the group consisting of a film of an oxide of the metal, a film where the metal oxide and another metal are mixed, and a laminated film of the metal oxide and another metal.

13. The piezoelectric device according to claim 12, wherein
a metal employed for the cap layer is one selected from the group consisting of an aluminum (Al), a titanium (Ti), a vanadium (V), a zirconium (Zr), a niobium (Nb), a molybdenum (Mo), a hafnium (Hf), a tantalum (Ta), and a tungsten (W).

14. A method for fabricating a piezoelectric device, comprising:
preparing a piezoelectric vibrating piece that includes an electrode and an exposed portion; and
forming a coating layer using a material with a sputtering rate lower than a sputtering rate of a material of the electrode so as to cover the exposed portion.

15. The method for fabricating a piezoelectric device according to claim 14, wherein
the material of the coating layer is formed of an insulator or a dielectric.

16. The method for fabricating a piezoelectric device according to claim 15, further comprising:
mounting the piezoelectric vibrating piece on a base; and
bonding a lid to the base using an ion-beam activation bonding.

17. The method for fabricating a piezoelectric device according to claim 16, wherein
the forming is performed after the mounting.

18. The method for fabricating a piezoelectric device according to claim 15, further comprising:
preparing the piezoelectric vibrating piece that includes a vibrating portion, a framing portion, and an anchor portion, the framing portion surrounding the vibrating portion, the anchor portion connecting the vibrating portion and the framing portion;
bonding the base on a back surface of the framing portion; and
bonding a lid to a front surface of the framing portion using an ion-beam activation bonding.

19. The method for fabricating a piezoelectric device according to claim 18, wherein
the forming is performed after the bonding the base.

20. The method for fabricating a piezoelectric device according to claim 17, wherein
the forming forms a coating layer at an exposed portion of the base.
